(19) United States
(12) Patent Application Publication
(10) Pub. No.: US 2024/0357872 A1
(43) Pub. Date: Oct. 24, 2024

(54) DISPLAY DEVICE AND METHOD OF PROVIDING THE SAME

(71) Applicant: Samsung Display Co., LTD., Yongin-si (KR)

(72) Inventors: Jin Ho HWANG, Yongin-si (KR); Sang Jin PARK, Yongin-si (KR)

(21) Appl. No.: 18/528,982

(22) Filed: Dec. 5, 2023

(30) Foreign Application Priority Data
Apr. 24, 2023 (KR) 10-2023-0053480

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes a pixel defining layer on a substrate and including a bank including first through third bank layers, in order from the substrate, an inorganic pixel defining layer between the bank and the substrate, and the bank together with the inorganic pixel defining layer defining a light emission opening, an a light emitting element in the light emission opening. Each of the first and third bank layers has a side surface which defines the light emission opening, the third bank layer protrudes further than the side surface of the first bank layer to define a tip of the third bank layer which defines the side surface of the third bank layer, and the side surface of the third bank layer is inclined relative to the substrate and defines an inclined side surface of the third bank layer.

This application claims priority to Korean Patent Application No. 10-2023-0053480, filed on Apr. 24, 2023, and all the benefits accruing therefrom under 35 U.S.C. § 119, the content of which in its entirety is herein incorporated by reference.

### BACKGROUND

### 1. Field

The present disclosure relates to a display device and a method of providing the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices.

Among these flat panel display devices, a light emitting display device includes a light emitting element that enables each pixel of a display panel to emit light by itself (e.g., self-emit light). Thus, the light emitting display device can display an image without a backlight unit that provides light to the display panel.

### SUMMARY

Aspects of the present disclosure provide a display device which reduces inflow of moisture and oxygen through an electrode pattern located on a bank structure.

Aspects of the present disclosure also provide a display device which improves defects caused by moisture by separating an electrode pattern located on a bank structure from a common electrode located on a light emitting element.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

An embodiment of a display device includes a substrate, an inorganic pixel defining layer on the substrate, a bank structure defining an opening and located on the inorganic pixel defining layer, a first pixel electrode overlapping the opening and disposed on the substrate, a first light emitting layer on the first pixel electrode and a first common electrode on the first light emitting layer, where the opening is located between neighboring of the two bank structure, and the bank structure includes a first bank layer on the inorganic pixel defining layer, a second bank layer on the first bank layer and a third bank layer on the second bank layer, where the third bank layer includes a tip protruding more than a side surface of the first bank layer, and the protruding tip of the third bank layer includes a first inclined surface inclined toward the substrate and a first side surface facing the opening and connected to the first inclined surface.

In an embodiment, the second bank layer may further include a side surface facing the opening, and the side surface of the second bank layer and the first inclined surface of the third bank layer do not contact each other.

In an embodiment, an angle defined by the side surface of the second bank layer and the first inclined surface of the third bank layer may be an acute angle.

In an embodiment, a thickness of the first bank layer may be greater than thicknesses of the second bank layer and the third bank layer, and the thickness of the third bank layer may be greater than the thickness of the second bank layer.

In an embodiment, the side surface of the first bank layer may be oblique to a first direction, the side surface of the second bank layer may be parallel to a direction perpendicular to the first direction, and the side surface of the first bank layer overlaps the protruding tip of the third bank layer.

In an embodiment, the inorganic pixel defining layer does not contact an upper surface of the first pixel electrode, a portion of the first light emitting layer may be disposed between the pixel electrode and the inorganic pixel defining layer, and a portion in which the first light emitting layer and the inorganic pixel defining layer contact each other overlaps the protruding tip of the third bank layer.

In an embodiment, the display device may include the first light emitting layer contacts the side surface of the first bank layer, and the first common electrode contacts the side surface of the first bank layer and the side surface of the second bank layer.

In an embodiment, a contact area between the first common electrode and the first bank layer may be larger than a contact area between the first light emitting layer and the first bank layer, and a portion in which the first common electrode and the first light emitting layer contact the first bank layer overlaps the protruding tip of the third bank layer.

In an embodiment, the first bank layer and the second bank layer may be conductors, and the third bank layer may be an insulator.

In an embodiment, the first bank layer may be aluminum (Al), the second bank layer may be molybdenum (Mo), and the third bank layer may be silicon nitride (SiNx).

In an embodiment, the display device may further include a second pixel electrode spaced apart from the first pixel electrode with the inorganic pixel defining layer interposed therebetween, a second light emitting layer on the second pixel electrode, a second common electrode on the second light emitting layer; and a thin-film encapsulation layer disposed on the first common electrode, the second common electrode, and the bank structure, where the thin-film encapsulation layer includes a first encapsulation layer, a second encapsulation layer on the first encapsulation layer and a third encapsulation layer on the second encapsulation layer, the first encapsulation layer further includes a first inorganic layer disposed on the first common electrode and the third bank layer and a second inorganic layer disposed on the second common electrode and the third bank layer, and the first inorganic layer and the second inorganic layer are spaced apart from each other.

In an embodiment, the bank structure and the second encapsulation layer may contact each other in a portion between the first inorganic layer and the second inorganic layer spaced apart from each other.

In an embodiment, each of the first inorganic layer and the second inorganic layer may cover the first inclined surface and the first side surface of the third bank layer in a portion overlapping the protruding tip of the third bank layer.

An embodiment of a display device includes a substrate; an inorganic pixel defining layer on the substrate; a bank structure defining an opening and located on the inorganic pixel defining layer; a first pixel electrode overlapping the opening and disposed on the substrate; a first light emitting layer on the first pixel electrode; and a first common electrode on the first light emitting layer, where the opening is located between neighboring of the two bank structure, and the bank structure includes a first bank layer on the inorganic pixel defining layer, a second bank layer on the first bank layer, a third bank layer on the second bank layer and a fourth bank layer on the third bank layer, where each of the third bank layer and the fourth bank layer includes a tip protruding more than side surfaces of the first bank layer and the second bank layer, the protruding tip of the third bank layer includes a first inclined surface inclined toward the substrate and a first side surface facing the opening and connected to the first inclined surface, and the protruding tip of the fourth bank layer includes a second inclined surface inclined toward the substrate and a second side surface facing the opening and connected to the second inclined surface.

In an embodiment, the display device may further include a first organic pattern disposed on the fourth bank layer to surround the opening and including the same material as the first light emitting layer; and a first electrode pattern disposed on the first organic pattern and including the same material as the first common electrode, where the first organic pattern and the first electrode pattern cover the first side surface of the third bank layer, the second inclined surface of the fourth bank layer, and the second side surface of the fourth bank layer in an area overlapping the protruding tip of the fourth bank layer.

In an embodiment, the first electrode pattern may include a cover surface partially covering the first inclined surface of the third bank layer, and the cover surface may overlap the protruding tip of each of the third bank layer and the fourth bank layer.

In an embodiment, the first electrode pattern and the first common electrode may be spaced apart from each other.

In an embodiment, the second inclined surface of the fourth bank layer may be parallel to the first inclined surface of the third bank layer, and the second side surface of the fourth bank layer may be aligned with the first side surface of the third bank layer.

In an embodiment, a thickness of the fourth bank layer may be smaller than a thickness of the third bank layer.

An embodiment of a method of fabricating (or providing) a display device includes a step of forming (or providing) a substrate including a light emitting area and a non-light emitting area, providing a first bank material layer, a second bank material layer, a third bank material layer and a fourth bank material layer completely covering a sacrificial layer and a pixel defining layer completely covering the substrate, forming a first hole through a dry etching process which overlaps an anode among the plurality of anode electrodes to penetrate the third bank material layer and the fourth bank material layer and expose the second bank material layer, forming removing the sacrificial layer by wet etching, and forming a tip in which the third bank material layer and the fourth bank material layer protrude from the sidewalls of the first bank material layer and the second bank material layer, forming a light emitting layer and a cathode electrode on the plurality of anode electrodes and the fourth bank material layer, forming a first encapsulation layer on the cathode electrode, and removing the light emitting layer, the cathode electrode and first encapsulation layer located in areas except for the light emitting layer, the cathode electrode and first encapsulation layer located around the light emitting area, wherein sidewalls of the third and fourth bank material layer define the tip and are inclined in a direction toward the substrate.

It should be noted that effects of the present disclosure are not limited to those described above and other effects of the present disclosure will be apparent to those skilled in the art from the following descriptions.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of an electronic device according to an embodiment;

FIG. 2 is a perspective view of a display device included in the electronic device according to the embodiment;

FIG. 3 is a cross-sectional view of the display device of FIG. 2 as viewed from the side;

FIG. 4 is a plan view of a display layer of a display device according to an embodiment;

FIG. 5 is a plan view illustrating the arrangement of emission areas in a first display area of the display device according to the embodiment;

FIG. 6 is a cross-sectional view taken along line X1-X1′ of FIG. 5;

FIG. 7 is an enlarged cross-sectional view of a first emission area of FIG. 6;

FIG. 8 is an enlarged view of area ‘A’ of FIG. 7;

FIG. 9 is a cross-sectional view of the first emission area and a second emission area of FIG. 6;

FIG. 10 is an enlarged view of area ‘C’ of FIG. 9; and

FIGS. 11 through 17 are cross-sectional views sequentially illustrating a display area during a process of fabricating (or providing) a display device according to an embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions is exaggerated for clarity.

It will also be understood that when a layer is referred to as being related to another element such as being “on” another layer or substrate, it can be directly on the other layer or substrate, or intervening layers may also be present. In contrast, when an element is referred to as being related to another element such as being “directly on” another element, there are no intervening elements present.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described with reference to the accompanying drawings.

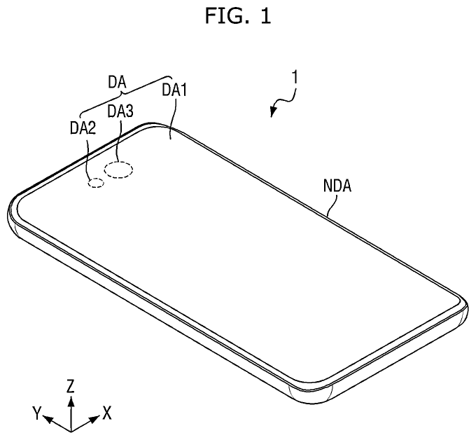

FIG. 1 is a schematic perspective view of an electronic device 1 according to an embodiment.

Referring to FIG. 1, the electronic device 1 displays moving images or still images. The electronic device 1 may refer to any electronic device that provides a display screen. Examples of the electronic device 1 may include a television, a notebook computer, a monitor, a billboard, an Internet of things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera and a camcorder, all of which provide a display screen.

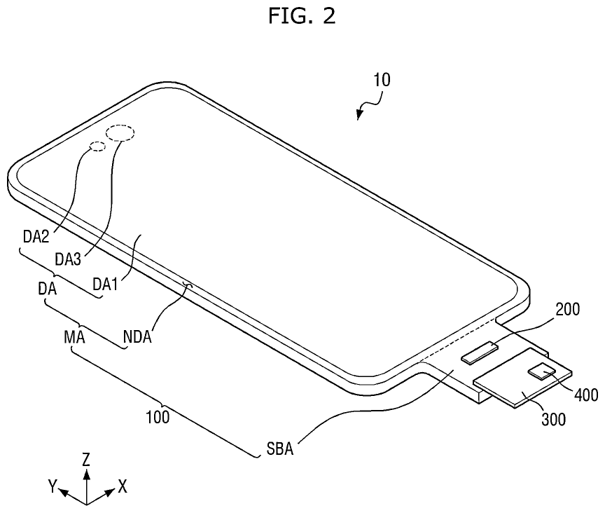

The electronic device 1 may include a display device 10 (see FIG. 2) that provides a display screen. Examples of the display device 10 may include an inorganic light emitting diode display device, an organic light emitting display device, a quantum dot light emitting display device, a plasma display panel, and a field emission display device. A case where an organic light emitting diode display device is applied as an example of the display device 10 will be described below, but the present disclosure is not limited to this case, and other display devices can also be applied as long as the same technical spirit is applicable.

The shape of the electronic device 1 can be variously modified. For example, the electronic device 1 may have various planar shapes such as a horizontally long rectangle, a vertically long rectangle, a square, a quadrilateral with rounded corners (vertices), other polygons, and a circle. The planar shape of a display area DA of the electronic device 1 may also be similar to the overall shape of the electronic device 1. In FIG. 1, the electronic device 1 is shaped like a rectangle that is long in a second direction Y and short in a first direction X.

The electronic device 1 may include the display area DA and a non-display area NDA. The display area DA may be an area (e.g., a planar area) where a display screen is provided and an image can be displayed. The non-display area NDA may be an area where no screen is provided and/or no image is displayed. The display area DA may also be referred to as an active area, and the non-display area NDA may also be referred to as an inactive area. The display area DA may generally occupy a center of the electronic device 1, such as to be spaced apart from outer edges of the display device 10 (or the electronic device 1).

The display area DA may include a first display area DA1, a second display area DA2, and a third display area DA3. The second display area DA2 and the third display area DA3 may be planar areas where components for adding various functions (e.g., a functional component) to the electronic device 1 are disposed. The second display area DA2 and the third display area DA3 may be component areas or function component areas.

FIG. 2 is a perspective view of the display device 10 included in the electronic device 1 according to the embodiment.

Referring to FIG. 2, the electronic device 1 according to the embodiment may include the display device 10. The display device 10 may provide a screen at which the image is displayed by the electronic device 1. The display device 10 may have a planar shape similar to that of the electronic device 1. For example, the display device 10 may be shaped like a rectangle having short sides in the first direction X and long sides in the second direction Y. Each corner where a short side extending in the first direction X meets a long side extending in the second direction Y may be rounded with a predetermined curvature. However, the present disclosure is not limited thereto, and each corner may also be right-angled. The planar shape of the display device 10 is not limited to a quadrilateral shape but may also be another polygonal shape, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image, and a non-display area NDA which is adjacent to the display area DA in a plan view (e.g., a view along a third direction Z). In an embodiment, the non-display area may be disposed around the display area DA. The display area DA may include a first display area DA1, a second display area DA2, and a third display area DA3. The plural display areas of the display device 10 may respectively correspond to those described above for the electronic device 1. The display area DA may emit light from a plurality of light emission areas or a plurality of opening areas of the display panel 100. For example, the display panel 100 may include pixel circuits including switching elements, a pixel defining layer defining the emission areas or the opening areas, and self-light emitting elements variously connected to the switching elements to emit the light.

For example, the self-light emitting elements having a light emitting layer may include at least one of, but not limited to, an organic light emitting diode including an organic light emitting layer, a quantum dot light emitting diode including a quantum dot light emitting layer, an inorganic light emitting diode including an inorganic semiconductor, and a micro-light emitting diode.

The non-display area NDA may be an area outside the display area DA. The non-display area NDA may form a boundary with the display area DA. The non-display area NDA may be defined as an edge area of the main area MA of the display panel 100. The non-display area NDA may include a gate driver (not illustrated) supplying gate signals to gate lines of the display area DA, and fan-out lines (not illustrated) connecting the display driver 200 and the display area DA to each other.

The sub-area SBA may be an area extending from a side of the main area MA, such a from an outer edge of the non-display area NDA. In an embodiment, the sub-area SBA and the non-display area NDA may together define a non-display area NDA of the display device 10

The sub-area SBA may include a flexible material that can be bent, folded, rolled, etc. That is, the display device 10 may be bendable, foldable, rollable, etc. at the sub-area SBA. For example, when the sub-area SBA is bent, the sub-area SBA may face or be overlapped by the main area MA in (or along) a thickness direction (a third direction Z). Various components or layers of the display device 10 (or the display panel 100) may be defined along the thickness direction. The sub-area SBA may include the display driver 200 and a pad unit at which the display panel 100 is connected to the circuit board 300. In an embodiment, the sub-area SBA may be omitted, and the display driver 200 and the pad unit may be disposed in the non-display area NDA.

The display driver 200 may output electrical signals and voltages for driving the display panel 100. The display driver 200 may supply data voltages as electrical signals, to data lines. The display driver 200 may supply a power supply voltage as an electrical signal, to a power line and supply a gate control signal as an electrical signal, to the gate driver.

The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA, and may be overlapped by the main area MA in the thickness direction by the display device 10 which is bent at the sub-area SBA. For another example, the display driver 200 may be mounted on the circuit board 300.

The circuit board 300 as an external component may be attached to the display panel 100, at the pad unit of the display panel 100, such as by using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal as an electrical signal, to a plurality of touch electrodes of the touch sensing unit and sense a change in capacitance between the touch electrodes. For example, the touch driving signal may be a pulse signal having a predetermined frequency. The touch driver 400 may calculate whether an input has been made relative to the display device 10 (or to the electronic device 1) and determine coordinates of the input based on a change in capacitance between the touch electrodes. The touch driver 400 may be formed as an integrated circuit.

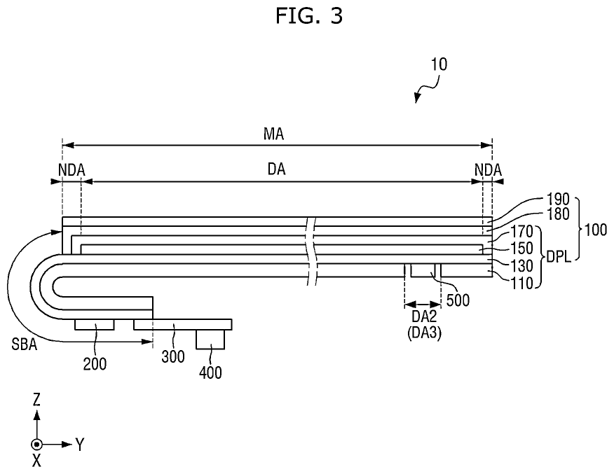

FIG. 3 is a cross-sectional view of the display device 10 of FIG. 2 as viewed from the side.

Referring to FIG. 3, the display panel 100 may include a display layer DPL, a touch sensing layer 180, and a color filter layer 190, in order along the thickness direction. In addition, the display layer DPL may include a substrate 110, a thin-film transistor layer 130 as a transistor layer, a light emitting element layer 150, and a thin-film encapsulation layer 170 as an encapsulation layer.

The substrate 110 may be a base substrate or a base member. The substrate 110 will be described later.

The thin-film transistor layer 130 may be disposed on the substrate 110. The thin-film transistor layer 130 may include a plurality of transistors such as thin-film transistors constituting pixel circuits of pixels. The thin-film transistor layer 130 may further include gate lines, data lines, power lines, gate control lines, fan-out lines connecting the display driver 200 and the data lines to each other, and lead lines connecting the display driver 200 and the pad unit of the display panel 100 to each other. Each of the thin-film transistors may include a semiconductor region, a source electrode, a drain electrode, and a gate electrode. For example, when the gate driver is formed or provided at a side of the non-display area NDA of the display panel 100, the gate driver may include thin-film transistors.

The thin-film transistor layer 130 may be disposed in each of the display area DA, the non-display area NDA, and the sub-area SBA. The thin-film transistors of the pixels, the gate lines, the data lines, and the power lines of the thin-film transistor layer 130 may be disposed in the display area DA. The gate control lines and the fan-out lines of the thin-film transistor layer 130 may be disposed in the non-display area NDA.

The light emitting element layer 150 may be disposed on the thin-film transistor layer 130. The light emitting element layer 150 may include a plurality of light emitting elements each including a first electrode, a second electrode and a light emitting layer to emit light, together with a pixel defining layer defining the pixels. The light emitting elements of the light emitting element layer 150 may be disposed in the display area DA.

In an embodiment, the light emitting layer may be an organic light emitting layer including an organic material. The light emitting layer may include a hole transporting layer, an organic light emitting layer, and an electron transporting layer. When the first electrode of a light emitting element receives a voltage through a thin-film transistor of the thin-film transistor layer 130 and the second electrode of the light emitting element receives a cathode voltage, holes and electrons may move to the organic light emitting layer of the light emitting element through the hole transporting layer and the electron transporting layer, respectively, and may be combined with each other in the organic light emitting layer to emit light. In an embodiment, the light emitting elements may include a quantum dot light emitting diode including a quantum dot light emitting layer, an inorganic light emitting diode including an inorganic semiconductor, or a micro-light emitting diode.

The encapsulation layer such as the thin-film encapsulation layer 170 may cover upper and side surfaces of the light emitting element layer 150 and may protect the light emitting element layer 150 from things such as moisture, oxygen, etc. The thin-film encapsulation layer 170 may include at least one inorganic layer and at least one organic layer to encapsulate the light emitting element layer 150.

The touch sensing layer 180 may be disposed on the thin-film encapsulation layer 170. The touch sensing layer 180 may include a plurality of touch electrodes for sensing an external touch such as a user's touch in a capacitive manner, and touch lines which connect the touch electrodes and the touch driver 400 to each other. For example, the touch sensing layer 180 may sense a user's touch in a mutual capacitance manner or a self-capacitance manner. In an embodiment, the touch sensing layer 180 may be disposed on a separate substrate disposed on the display layer DPL which is different from the substrate 110 thereof. In this case, the second substrate that supports the touch sensing layer 180 may be a base member that encapsulates the display layer DPL to have a dual purpose as both a base member and an encapsulating member.

The touch electrodes of the touch sensing layer 180 may be disposed in a touch sensor area overlapping or corresponding to the display area DA. The touch lines of the touch sensing layer 180 may be disposed in a touch peripheral area overlapping or corresponding to the non-display area NDA.

The display device 10 may further include an optical device 500. The optical device 500 may be disposed in the second display area DA2 and/or the third display area DA3. The optical device 500 may emit and/or receive light in an infrared, ultraviolet, or visible light band, such as to provide a function to the display device 10 using light. For example, the optical device 500 may be an optical sensor that senses light incident on the display device 10, such as a proximity sensor, an illuminance sensor, a camera sensor or an image sensor.

The color filter layer 190 may be disposed on the thin-film encapsulation layer 170 to overlap emission areas (e.g., light emission areas). The color filter layer 190 may include a plurality of color filters corresponding to the emission areas, respectively. Each of the color filters may selectively transmit light of a specific wavelength and block or absorb light of other wavelengths. The color filter layer 190 may absorb a portion of light introduced from the outside of the display device 10 (e.g., external light) to reduce reflected light due to the external light. Therefore, the color filter layer 190 can prevent color distortion due to reflection of the external light.

Since the color filter layer 190 is directly disposed on the thin-film encapsulation layer 170, the display device 10 may not require a separate substrate for the color filter layer 190. That is, the encapsulation layer may have a dual function as both a base member to the color filter layer 190 and an encapsulating member. Therefore, a total thickness of the display device 10 may be relatively small.

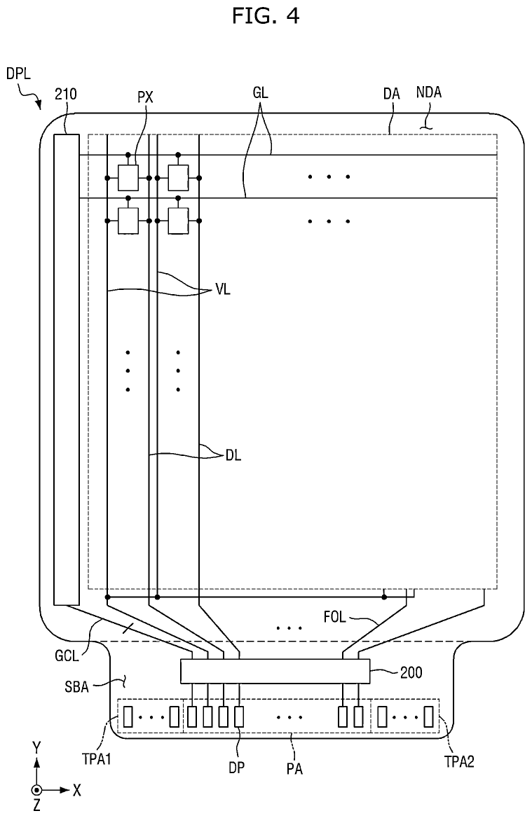

FIG. 4 is a plan view of a display layer DPL of a display device 10 according to an embodiment.

Referring to FIG. 4, the display layer DPL may include a display area DA and a non-display area NDA.

The display area DA may be disposed in a center of a display panel 100 or spaced apart from an outer edge of the display layer DPL. In the display area DA, a pixel PX provided in plural including a plurality of pixels PX, a gate line GL provided in plural including a plurality of gate lines GL, a data line DL provided in plural including a plurality of data lines DL, and a power line VL provided in plural including a plurality of power lines VL may be disposed. Each of the pixels PX may be defined as a minimum unit or a display unit that emits light.

The gate lines GL may supply gate signals received from a gate driver 210, to the pixels PX. The gate lines GL may extend in (or along) the first direction X and may be spaced apart from each other in (or along) the second direction Y which intersects the first direction X.

The data lines DL may supply data voltages received from a display driver 200, to the pixels PX. The data lines DL may extend in the second direction Y and may be spaced apart from each other in the first direction X.

The power lines VL may supply a power supply voltage received from the display driver 200, to the pixels PX. Here, the power supply voltage may be at least one of a driving voltage, an initialization voltage, a reference voltage, and a low-potential voltage. The power lines VL may extend in the second direction Y and may be spaced apart from each other in the first direction X.

The non-display area NDA may extend along sides or edges of the display area DA, such as to surround the display area DA. In the non-display area NDA, the gate driver 210, fan-out lines FOL, and gate control lines GCL may be disposed.

The gate driver 210 may generate a plurality of gate signals based on a gate control signal and sequentially supply the gate signals to the gate lines GL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

A sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL, through the fan-out lines FOL. The data voltages may be supplied to the pixels PX and may control luminances of the pixels PX. The display driver 200 may supply a gate control signal to the gate driver 210, through the gate control lines GCL.

The pad area PA, the first touch pad area TPA1, and the second touch pad area TPA2 may be disposed at an edge of the display device 10 which is defined by the sub-area SBA. The pad area PA, the first touch pad area TPA1, and the second touch pad area TPA2 of the display panel 100 may be electrically connected to a circuit board 300 using an anisotropic conductive film or a material such as self-assembly anisotropic conductive paste (SAP).

The pad area PA of the display panel 100 may include a display pad provided in plural including a plurality of display pad units DP. The display pad units DP may be connected to a graphics system, through the circuit board 300. The display pad units DP may be connected to the circuit board 300 to receive digital video data and may supply the digital video data to the display driver 200.

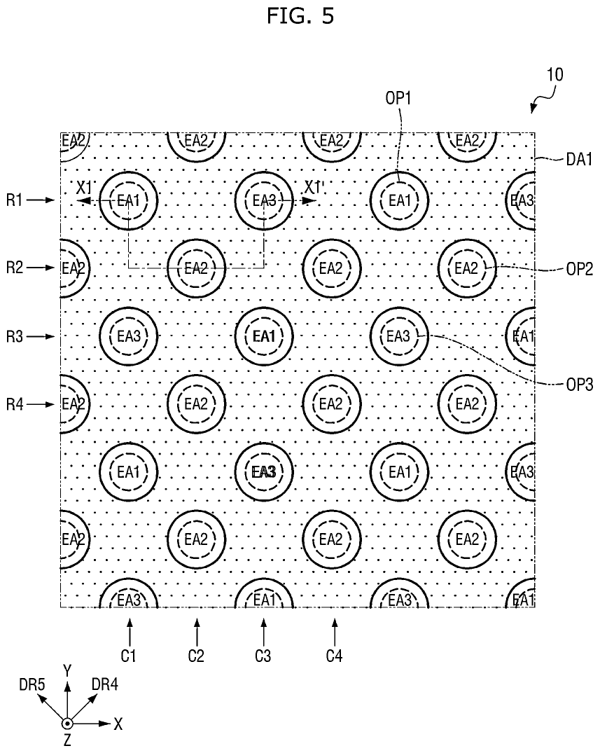

FIG. 5 is a plan view illustrating the arrangement of emission areas EA1 through EA3 as light emission areas, in a first display area DA1 of the display device 10 according to the embodiment.

Referring to FIG. 5, the display device 10 may include a plurality of emission areas EA1 through EA3 disposed in the display area DA. The portion of the display area DA illustrated in FIG. 5 may be the first display area DA1, and the emission areas EA1 through EA3 may be disposed in the first display area DA1. However, the emission areas EA1 through EA3 may also be disposed in a second display area DA2 and/or a third display area DA3 of the display area DA.

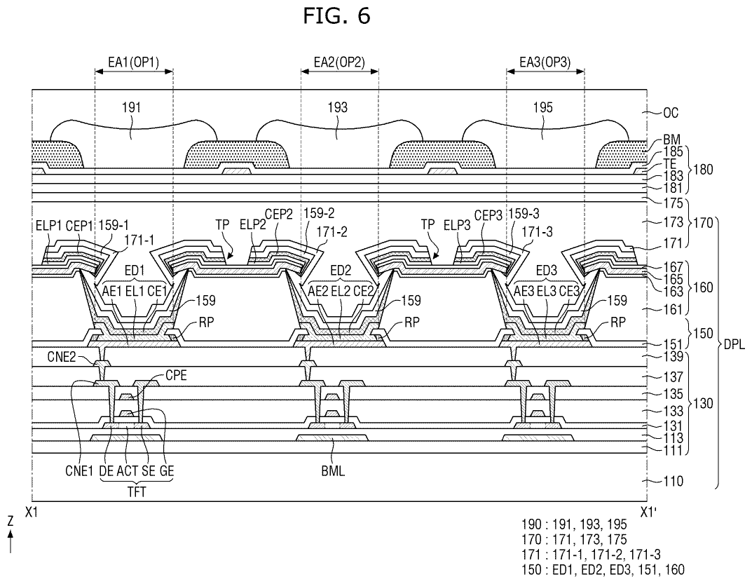

The emission areas EA1 through EA3 may include first emission areas EA1, second emission areas EA2, and third emission areas EA3 that emit light of different colors from each other. Each of the first through third emission areas EA1 through EA3 may emit red, green or blue light, and the color of light emitted from each of the emission areas EA1 through EA3 may vary according to the type of light emitting element ED1, ED2 or ED3 (see FIG. 6) disposed in a light emitting element layer 150 which will be described later. In an embodiment, the first emission areas EA1 may emit red first light, the second emission areas EA2 may emit green second light, and the third emission areas EA3 may emit blue third light. However, the present disclosure is not limited thereto.

The emission areas EA1 through EA3 may be arranged in a PenTile™ type arrangement, for example, a diamond PenTile™ type. For example, the first emission areas EA1 and the third emission areas EA3 may be spaced apart from each other in the first direction X, and may be alternately disposed in both the first direction X and the second direction Y. In the arrangement of the emission areas EA1 through EA3, the first emission areas EA1 and the third emission areas EA3 may be alternately disposed in the first direction X, along a respective emission row, such as in a first row R1 and a third row R3. The first emission areas EA1 and the third emission areas EA3 may be alternately disposed in the second direction Y, along a respective emission column, such as in a first column C1 and a third column C3.

Each of the second emission areas EA2 may be spaced apart from other adjacent second emission areas EA2 in the first direction X and the second direction Y, and may be spaced apart from adjacent first and third emission areas EA1 and EA3 in a respective inclined direction, such as a fourth direction DR4 and/or a fifth direction DR5. The second emission areas EA2 may be repeatedly disposed along the first direction X and the second direction Y. The second emission areas EA2 and the first emission areas EA1 or the second emission areas EA2 and the third emission areas EA3 may be alternately disposed along the fourth direction DR4 or the fifth direction DR5. In the arrangement of the emission areas EA1 through EA3, the second emission areas EA2 may be repeatedly disposed in the first direction X in a second row R2 and a fourth row R4, and may be repeatedly disposed in the second direction Y in a second column C2 and a fourth column C4.

The first through third emission areas EA1 through EA3 may be respectively defined by a plurality of openings OP1 through OP3 formed or provided in an inorganic pixel defining layer 151 (see FIG. 6) of the light emitting element layer 150, together with a bank structure 160 (see FIG. 6) which will be described later.

FIG. 6 is a cross-sectional view of a portion of the display device 10 according to the embodiment.

FIG. 6 is a partial cross-sectional view of the display device 10, illustrating cross-sections of a substrate 110, a thin-film transistor layer 130, the light emitting element layer 150, a thin-film encapsulation layer 170, a touch sensing layer 180, and a color filter layer 190.

Referring to FIG. 6, the display layer DPL may include the substrate 110, the thin-film transistor layer 130, the light emitting element layer 150, and the thin-film encapsulation layer 170.

The substrate 110 may be a base substrate or a base member. The substrate 110 may be a flexible substrate that can be bent, folded, rolled, etc. For example, the substrate 110 may include polymer resin such as polyimide (PI). However, the present disclosure is not limited thereto. For another example, the substrate 110 may include a glass material or a metal material.

The thin-film transistor layer 130 may include a first buffer layer 111, a bottom metal pattern layer including bottom metal layers BML, a second buffer layer 113, plural transistors such as thin-film transistors TFT, a gate insulating layer 131, a first interlayer insulating layer 133, a capacitor electrode layer including capacitor electrodes CPE, a second interlayer insulating layer 135, a first connection electrode layer including first connection electrodes CNE1, a first passivation layer 137, a second connection electrode layer including second connection electrodes CNE2, and a second passivation layer 139.

The first buffer layer 111 may be disposed on the substrate 110. The first buffer layer 111 may include an inorganic layer that can prevent penetration of air or moisture. For example, the first buffer layer 111 may include a plurality of inorganic layers stacked along a thickness direction.

The bottom metal layers BML may be disposed on the first buffer layer 111. For example, each of the bottom metal layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer 113 may cover the first buffer layer 111 and the bottom metal layers BML. The second buffer layer 113 may include an inorganic layer that can prevent penetration of air or moisture. For example, the second buffer layer 113 may include a plurality of inorganic layers stacked along the thickness direction.

The thin-film transistors TFT may be disposed on the second buffer layer 113 and may constitute respective pixel circuits of a plurality of pixels PX. For example, each of the thin-film transistors TFT may be a driving transistor or a switching transistor of a pixel circuit. Each of the thin-film transistors TFT may include a semiconductor layer ACT, a source electrode SE, a drain electrode DE, and a gate electrode GE.

The semiconductor layer ACT may be disposed on the second buffer layer 113. The semiconductor layer ACT may overlap or be aligned with a bottom metal layer BML and the gate electrode GE in the thickness direction, and may be insulated from the gate electrode GE by the gate insulating layer 131. In portions of the semiconductor layer ACT which are defined in a direction along the transistor layer, the material of the semiconductor layer ACT may be made conductive to form the source electrode SE and the drain electrode DE as conductive electrodes of a respective transistor.

The gate electrode GE may be disposed on the gate insulating layer 131. The gate electrode GE may overlap or face the semiconductor layer ACT with the gate insulating layer 131 interposed between them.

The gate insulating layer 131 may be disposed on the semiconductor layers ACT. For example, the gate insulating layer 131 may cover the semiconductor layers ACT and the second buffer layer 113 and may insulate the semiconductor layers ACT from the gate electrodes GE. The gate insulating layer 131 may include or define contact holes through which the first connection electrodes CNE1 pass.

The first interlayer insulating layer 133 may cover the gate electrodes GE and the gate insulating layer 131. The first interlayer insulating layer 133 may include or define contact holes through which the first connection electrodes CNE1 pass. The contact holes of the first interlayer insulating layer 133 may be respectively connected to the contact holes of the gate insulating layer 131 and the contact holes of the second interlayer insulating layer 135 so as to form a continuous contact hole.

The capacitor electrodes CPE may be disposed on the first interlayer insulating layer 133. The capacitor electrodes CPE may overlap the gate electrodes GE in the thickness direction. The capacitor electrodes CPE and the gate electrodes GE may together form capacitances of a capacitor.

The second interlayer insulating layer 135 may cover the capacitor electrodes CPE and the first interlayer insulating layer 133. The second interlayer insulating layer 135 may include or define the contact holes through which the first connection electrodes CNE1 pass. The contact holes of the second interlayer insulating layer 135 may be connected to or be in communication with the contact holes of the first interlayer insulating layer 133 and the contact holes of the gate insulating layer 131.

The first connection electrodes CNE1 may be disposed on the second interlayer insulating layer 135. The first connection electrodes CNE1 may electrically connect the drain electrodes DE of the thin-film transistors TFT to the second connection electrodes CNE2, respectively. The first connection electrodes CNE1 may be inserted into or extend through the contact holes formed in the second interlayer insulating layer 135, the first interlayer insulating layer 133 and the gate insulating layer 131 to contact the drain electrodes DE of the thin-film transistors TFT.

The first passivation layer 137 may cover the first connection electrodes CNE1 and the second interlayer insulating layer 135. The first passivation layer 137 may protect the thin-film transistors TFT. The first passivation layer 137 may include or define contact holes through which the second connection electrodes CNE2 pass.

The second connection electrodes CNE2 may be disposed on the first passivation layer 137. The second connection electrodes CNE2 may electrically connect the first connection electrodes CNE1 to pixel electrodes AE1 through AE3 of light emitting elements ED1 through ED3, respectively. The second connection electrodes CNE2 may be inserted into or extend through the contact holes formed in the first passivation layer 137 to contact the first connection electrodes CNE1.

The second passivation layer 139 may cover the second connection electrodes CNE2 and the first passivation layer 137. The second passivation layer 139 may include or define contact holes through which the pixel electrodes AE1 through AE3 of the light emitting elements ED1 through ED3 pass.

The light emitting element layer 150 may be disposed on the thin-film transistor layer 130. The light emitting element layer 150 may include the light emitting elements ED1 through ED3 together with the inorganic pixel defining layer 151 and the bank structure 160. Each of the light emitting elements ED1 through ED3 may include the pixel electrode AE1, AE2 or AE3, a light emitting layer EL1, EL2 or EL3, and a common electrode CE1, CE2 or CE3, respectively.

In some embodiments, the first through third emission areas EA1 through EA3 may have the same planar area or size in a direction along the transistor layer. For example, in the display device 10, the openings OP1 through OP3 which are defined by portions of the bank structure 160 may have the same diameter in the plan view, and the first through third emission areas EA1 through EA3 may therefore have the same planar area. However, the present disclosure is not limited thereto.

In the display device 10, the first through third emission areas EA1 through EA3 may also have different planar areas or sizes. For example, the planar area of each second emission area EA2 may be larger than the planar area of each first emission area EA1 and the planar area of each third emission area EA3, and the planar area of each third emission area EA3 may be larger than the planar area of each first emission area EA1. The intensity of light emitted from each of the emission areas EA1 through EA3 may vary according to the planar area of the emission area EA1, EA2 or EA3, and the color of an image displayed on a display screen the display device 10 or the electronic device 1 may be controlled by adjusting the planar area of each of the emission areas EA1 through EA3.

In the embodiment of FIGS. 5 and 6, the emission areas EA1 through EA3 have the same planar area. However, the present disclosure is not limited thereto. The planar areas of the emission areas EA1 through EA3 may be freely adjusted according to the color of the image displayed by the display device 10 and the electronic device 1.

Referring to FIG. 6, in the display device 10, one first emission area EA1, one second emission area EA2, and one third emission area EA3 adjacent to each other may form one pixel group. One pixel group may include the emission areas EA1 through EA3 emitting light of different colors to express a white gray level at the pixel group. However, the present disclosure is not limited thereto, and the combination of the emission areas EA1 through EA3 constituting one pixel group can be variously modified according to the arrangement of the emission areas EA1 through EA3 and the colors of light emitted from the emission areas EA1 through EA3.

The display device 10 may include a plurality of light emitting elements ED1 through ED3 disposed in different respective emission areas EA1 through EA3. The light emitting elements ED1 through ED3 may include a first light emitting element ED1 disposed in the first emission area EA1, a second light emitting element ED2 disposed in the second emission area EA2, and a third light emitting element ED3 disposed in the third emission area EA3. The light emitting elements ED1 through ED3 may include the pixel electrodes AE1 through AE3, the light emitting layers EL1 through EL3, and the common electrodes CE1 through CE3, respectively.

The light emitting elements ED1 through ED3 disposed in different emission areas EA1 through EA3 may emit light of different colors depending on the materials of the light emitting layers EL1 through EL3. For example, the first light emitting element ED1 disposed in the first emission area EA1 may emit red light of a first color, the second light emitting element ED2 disposed in the second emission area EA2 may emit green light of a second color, and the third light emitting element ED3 disposed in the third emission area EA3 may emit blue light of a third color. The first through third emission areas EA1 through EA3 constituting one pixel PX may include the light emitting elements ED1 through ED3 emitting light of different colors to express a white gray level.

The pixel electrode layer including the pixel electrodes AE1 through AE3 may be disposed on the second passivation layer 139. Each of the pixel electrodes AE1 through AE3 may overlap any one of the openings OP1 through OP3 of the bank structure 160. The pixel electrodes AE1 through AE3 may be electrically connected to the drain electrodes DE of the thin-film transistors TFT, through the first and second connection electrodes CNE1 and CNE2.

The pixel electrodes AE1 through AE3 may be disposed in the emission areas EA1 through EA3, respectively. The pixel electrodes AE1 through AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other on the second passivation layer 139, in a direction along the light emitting element layer 150. The pixel electrodes AE1 through AE3 may be respectively disposed in different emission areas EA1 through EA3 to form the light emitting elements ED1 through ED3 emitting light of different colors.

In an embodiment, the pixel electrodes AE1 through AE3 may have a stacked structure of a material layer having a high work function such as indium tin oxide (ITO), indium zinc oxide (IZO), zinc oxide (ZnO) or indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a combination thereof. The material layer having a high work function may be disposed on the reflective material layer so that it is located closer to the light emitting layers EL1 through EL3 than the reflective material layer. For example, the pixel electrodes AE1 through AE3 may have, but not limited to, a multilayer structure along the thickness direction of ITO/Mg, ITO/MgF, ITO/Ag, or ITO/Ag/ITO.

The display device 10 may include the inorganic pixel defining layer 151 disposed on the second passivation layer 139 and on the pixel electrodes AE1 through AE3. In addition, the display device 10 may further include the bank structure 160 overlapping the thin-film transistor layer 130 and disposed on the inorganic pixel defining layer 151.

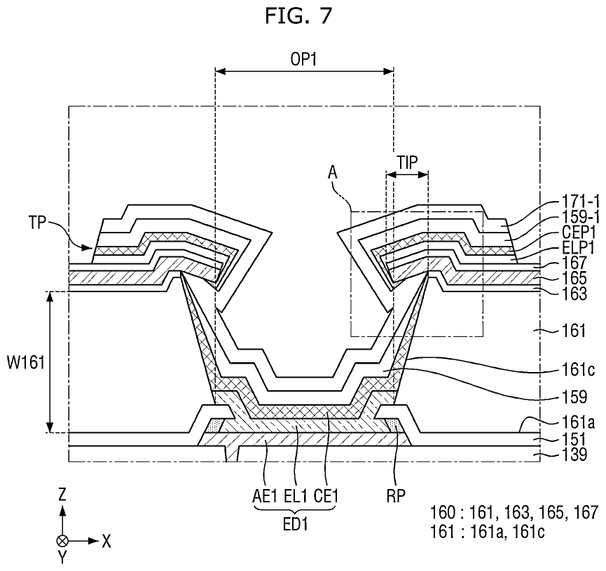

The inorganic pixel defining layer 151 and the bank structure 160 will be described in detail later with reference to FIG. 7.

The light emitting material layer including the light emitting layers EL1 through EL3 may be disposed on the pixel electrodes AE1 through AE3. The light emitting layers EL1 through EL3 may be organic light emitting layers made of including an organic material. In a method of providing the display device 10 (or the display panel 100), the light emitting material layer may be formed (or provided) on the pixel electrodes AE1 through AE3 through a deposition process. When the thin-film transistors TFT apply a predetermined voltage to the pixel electrodes AE1 through AE3 of the light emitting elements ED1 through ED3 together with the common electrodes CE1 through CE3 of the light emitting elements ED1 through ED3 receiving a common voltage or a cathode voltage, holes and electrons may move to the light emitting layers EL1 through EL3 through a hole transporting layer and an electron transporting layer within the light emitting material layer, respectively. Then, the holes and electrons may be combined with each other in the light emitting layers EL1 through EL3 to emit light.

The light emitting layers EL1 through EL3 may include a first light emitting layer EL1, a second light emitting layer EL2, and a third light emitting layer EL3 disposed in different emission areas EA1 through EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The first through third light emitting layers EL1 through EL3 may be light emitting layers of the first through third light emitting elements ED1 through ED3, respectively. The first light emitting layer EL1 may be a light emitting layer emitting red light of the first color, the second light emitting layer EL2 may be a light emitting layer emitting green light of the second color, and the third light emitting layer EL3 may be a light emitting layer emitting blue light of the third color.

According to an embodiment, portions of the light emitting layers EL1 through EL3 of the light emitting elements ED1 through ED3 may be disposed between the pixel electrodes AE1 through AE3 and the inorganic pixel defining layer 151, along the thickness direction. End portions of the inorganic pixel defining layer 151 may be disposed on the pixel electrodes AE1 through AE3 but may be spaced apart from upper surfaces of the pixel electrodes AE1 through AE3 along the thickness direction. Referring to FIG. 6, for example, within the pixel defining layer (160+151), the inorganic pixel defining layer 151 extends further than the side surface 161c of the first bank layer 161 to define an extended portion of the inorganic pixel defining layer 151, the extended portion being spaced apart from the upper surface of the pixel electrode, along the thickness direction. The light emitting layer extends between the upper surface of the pixel electrode and the extended portion of the inorganic pixel defining layer 151 and contacts the inorganic pixel defining layer 151 at a contact portion. The contact portion overlaps the tip TIP of the third bank layer 165, along the thickness direction.

In the deposition process of a method of providing the light emitting layers EL1 through EL3, the materials of the light emitting layers EL1 through EL3 may be deposited in a direction inclined to an upper surface of the substrate 110, rather than in a direction perpendicular to the upper surface of the substrate 110, where the upper surface may be parallel to a plane defined by the first direction X and the second direction Y crossing each other. Accordingly, the light emitting layers EL1 through EL3 may be formed on the upper surfaces of the pixel electrodes AE1 through AE3 which are exposed to outside the bank structure 160 through the openings OP1 through OP3 of the bank structure 160, and may fill empty spaces between the pixel electrodes AE1 through AE3 and the inorganic pixel defining layer 151 owing to the inclined deposition direction. For example, the empty spaces between the pixel electrodes AE1 through AE3 and the inorganic pixel defining layer 151 may be respectively open to outside the bank structure 160 in the inclined deposition direction.

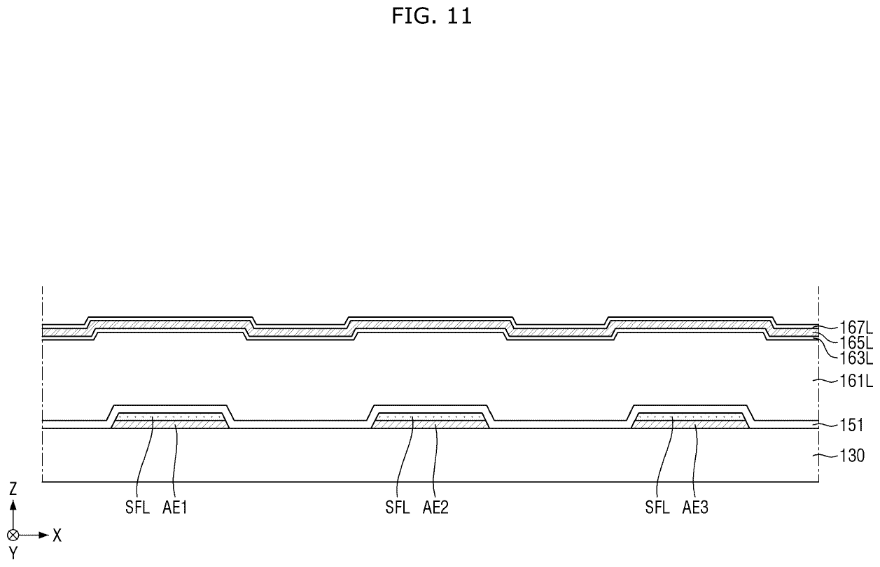

In a fabrication process of a method of providing the display device 10, sacrificial layers SFL (see FIG. 11) may be respectively disposed between the inorganic pixel defining layer 151, and the pixel electrodes AE1 through AE3, and the light emitting layers EL1 through EL3 may be respectively extended into the empty spaces defined at areas from which the sacrificial layers SFL are partially removed. Accordingly, a portion of a lower surface of the inorganic pixel defining layer 151 may be spaced apart from the pixel electrodes AE1 through AE3, where portions of the lower surface are respectively closest to the transistor layer. However, a remaining portion of the sacrificial layers SFL may remain as residual patterns RP in the spaces respectively defined between the inorganic pixel defining layer 151, and the pixel electrodes AE1 through AE3. Therefore, the empty areas between the inorganic pixel defining layer 151 and the pixel electrodes AE1 through AE3 may be filled, such as completely filled, with the residual patterns RP together with the light emitting layers EL1 through EL3.

The common electrode layer including the common electrodes CE1 through CE3 may be disposed on the light emitting layers EL1 through EL3. The common electrodes CE1 through CE3 may include a transparent conductive material to allow light generated by the light emitting layers EL1 through EL3 to pass therethrough. The common electrodes CE1 through CE3 may receive a common voltage or a low potential voltage. When the pixel electrodes AE1 through AE3 receive voltages corresponding to data voltages, together with the common electrodes CE1 through CE3 receiving a low potential voltage, a potential difference may be formed between the pixel electrodes AE1 through AE3 and the common electrode CE1 through CE3. Accordingly, the light emitting layers EL1 through ED3 may emit light.

In an embodiment, the common electrodes CE1 through CE3 may include a material layer having a small work function such as Li, Ca, LiF/Ca, LiF/Al, Al, Mg, Ag, Pt, Pd, Ni, Au Nd, Ir, Cr, BaF, Ba, or a combination thereof (e.g., a combination of Ag and Mg). The common electrodes CE1 through CE3 may further include a transparent metal oxide layer disposed on the material layer having a small work function.

The common electrodes CE1 through CE3 may include a first common electrode CE1, a second common electrode CE2, and a third common electrode CE3 disposed in different emission areas EA1 through EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3.

According to an embodiment, portions of the common electrodes CE1 through CE3 of the light emitting elements ED1 through ED3 may be disposed on the light emitting material layer and extend therefrom along side surfaces of a first bank layer 161 and a second bank layer 163 of the bank structure 160.

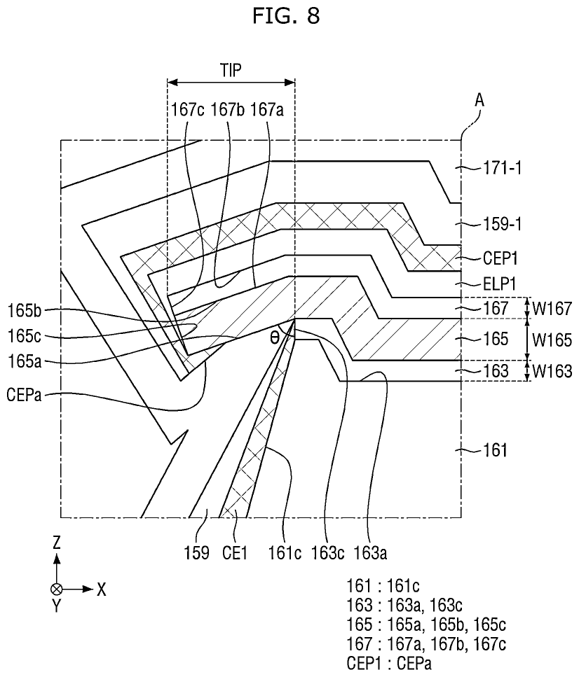

The arrangement structure of the common electrodes CE1 through CE3 and the bank structure 160 will be described later with reference to FIGS. 7 and 8.

A capping material layer including capping layers 159 may be disposed on the common electrodes CE1 through CE3. The capping layers 159 may include an inorganic insulating material to cover the light emitting elements ED1 through ED3 and various patterns disposed on or along the bank structure 160. The capping layers 159 may prevent the light emitting elements ED1 through ED3 from being damaged by external air and prevent the various patterns disposed on the bank structure 160 from being peeled off the bank structure 160 during a subsequent fabrication process in providing of the display device 10. In an embodiment, the capping layers 159 may include aluminum oxide, titanium oxide, tantalum oxide, hafnium oxide, zinc oxide, silicon oxide, silicon nitride, or silicon oxynitride.

The thin-film encapsulation layer 170 may be disposed on the light emitting elements ED1 through ED3 and the bank structure 160 and may cover the light emitting elements ED1 through ED3 and the bank structure 160. The thin-film encapsulation layer 170 may include at least one inorganic layer to prevent oxygen or moisture from penetrating into the light emitting element layer 150. The thin-film encapsulation layer 170 may include at least one organic layer to protect the light emitting element layer 150 from foreign substances such as dust.

In an embodiment, the thin-film encapsulation layer 170 may include a first encapsulation layer 171, a second encapsulation layer 173, and a third encapsulation layer 175 stacked sequentially in a direction away from the light emitting element layer 150. The first encapsulation layer 171 and the third encapsulation layer 175 may be inorganic encapsulation layers, and the second encapsulation layer 173 disposed between them may be an organic encapsulation layer.

Each of the first encapsulation layer 171 and the third encapsulation layer 175 may include one or more inorganic insulating materials. The inorganic insulating materials may include aluminum oxide, titanium oxide, tantalum oxide, hafnium oxide, zinc oxide, silicon oxide, silicon nitride, or silicon oxynitride.

The second encapsulation layer 173 may include a polymer-based material. Examples of the polymer-based material may include acrylic resin, epoxy resin, polyimide, and polyethylene. For example, the second encapsulation layer 173 may include acrylic resin such as polymethyl methacrylate or polyacrylic acid. The second encapsulation layer 173 may be formed by curing a monomer or applying a polymer.

The first encapsulation layer 171 may be disposed on the light emitting elements ED1 through ED3, a plurality of patterns, and the bank structure 160. The first encapsulation layer 171 may include a plurality of inorganic patterns such as a first inorganic layer 171-1, a second inorganic layer 171-2, and a third inorganic layer 171-3 disposed to correspond to different emission areas EA1 through EA3, respectively. Such patterns may be discrete patterns along a planar direction, without being limited thereto.

The first through third inorganic layers 171-1 through 171-3 may include an inorganic insulating material to cover the light emitting elements ED1 through ED3, respectively. The first through third inorganic layers 171-1 through 171-3 may prevent the light emitting elements ED1 through ED3 from being damaged by external air and may prevent the patterns disposed on the bank structure 160 from being peeled off during the fabrication process of the display device 10. Referring to FIG. 6, within the pixel defining layer (160+151), the bank 160 together with the inorganic pixel defining layer 151 define a plurality of light emission openings OP1 through OP3, the light emitting element provided in plural including a plurality of light emitting elements ED1 through ED3 spaced apart from each other along the substrate 110 with the inorganic pixel defining layer 151 therebetween, the plurality of light emitting elements respectively in the plurality of light emission openings. The encapsulation layer 170 is on the plurality of light emitting elements ED1 through ED3 and the pixel defining layer. The first encapsulation layer defines a plurality of inorganic patterns 171-1 through 171-3 which are spaced apart from each other and respectively on the plurality of light emitting elements, and the plurality of inorganic patterns 171-1 through 171-3 are respectively in the plurality of light emission openings and extended out of the plurality of light emission openings and along the third bank layer 165.

In an embodiment, the first through third inorganic layers 171-1 through 171-3 may include aluminum oxide, titanium oxide, tantalum oxide, hafnium oxide, zinc oxide, silicon oxide, silicon nitride, or silicon oxynitride.

In some embodiments, the first through third inorganic layers 171-1 through 171-3 may be respectively formed on the bank structure 160 and may extend from the bank structure 160 to be disposed in the emission areas EA1 through EA3 or the openings OP defined by the bank structure 160, to cover the light emitting elements ED1 through ED3, respectively. The bank structure 160 may include solid portions disconnected or spaced apart from each other to provide the openings OP therebetween.

The touch sensing layer 180 may be disposed on the thin-film encapsulation layer 170. The touch sensing layer 180 may include a touch buffer layer 181, a touch insulating layer 183, a touch electrode layer including touch electrodes TE, and a touch protection layer 185.

The touch buffer layer 181 may be disposed on the thin-film encapsulation layer 170. The touch buffer layer 181 may have insulating and optical functions. The touch buffer layer 181 may include at least one inorganic layer. Optionally, the touch buffer layer 181 may be omitted. Although not illustrated in the drawings, a touch connection electrode electrically connecting the touch electrodes to each other may be disposed on the touch buffer layer 181. The touch connection electrode may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/AI/ITO) of aluminum and indium tin oxide, an APC alloy, or a stacked structure (ITO/APC/ITO) of an APC alloy and indium tin oxide.

The touch insulating layer 183 may cover the touch buffer layer 181. The touch insulating layer 183 may have insulating and optical functions. For example, the touch insulating layer 183 may be an inorganic layer including at least one of a silicon nitride layer, a silicon oxynitride layer, a silicon oxide layer, a titanium oxide layer, and an aluminum oxide layer.

the touch electrodes TE may be disposed on the touch insulating layer 183. Each of the touch electrodes TE may not overlap the first through third emission areas EA1 through EA3. Each of the touch electrodes TE may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/AV/ITO) of aluminum and indium tin oxide, an APC alloy, or a stacked structure (ITO/APC/ITO) of an APC alloy and indium tin oxide.

The touch protection layer 185 may cover the touch electrodes TE and the touch insulating layer 183. The touch protection layer 185 may have insulating and optical functions. The touch protection layer 185 may be made of at least one of the example materials of the touch insulating layer 183.

A light blocking layer BM including a light blocking pattern may be disposed on the touch sensing layer 180. The light blocking layer BM may overlap the inorganic pixel defining layer 151 and the bank structure 160. That is, each of the light blocking layer BM, the inorganic pixel defining layer 151 and the bank structure 160 may have solid structures or solid portions which are spaced apart from each other along a plane and respectively define an opening or recess therebetween.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black. However, the present disclosure is not limited thereto. The light blocking layer BM may prevent color mixing between light emission areas by preventing intrusion of visible light respectively between the first through third emission areas EA1 through EA3, thereby improving a color gamut of the display device 10.

The color filter layer 190 may be disposed on the touch protection layer 185 and the light blocking layer BM to overlap the emission areas EA1 through EA3.

The color filter layer 190 may include a plurality of color filters including a first color filter 191, a second color filter 193, and a third color filter 195 disposed to correspond to different emission areas EA1 through EA3, respectively. Each of the color filters 191, 193 and 195 may include a colorant such as a dye or pigment that absorbs light in wavelength bands other than light in a specific wavelength band and may be disposed to correspond to the color of light emitted from one of the emission areas EA1 through EA3. For example, the first color filter 191 may be a red color filter that overlaps the first emission area EA1 and transmits only red first light. The second color filter 193 may be a green color filter that overlaps the second emission area EA2 and transmits only green second light, and the third color filter 195 may be a blue color filter that overlaps the third emission area EA3 and transmits only blue third light.

In FIG. 6, each of the color filters 191, 193 and 195 is spaced apart from other adjacent color filters 191, 193 and 195, on the light blocking layer BM. However, the present disclosure is not limited thereto. That is, each of the color filters 191, 193 and 195 may also partially overlap other adjacent color filters 191, 193 and 195. The different color filters 191, 193 and 195 may overlap each other on the light blocking layer BM in areas not overlapping the emission areas EA1 through EA3. As not overlapping, elements may be adjacent to each other or spaced apart from each other, in a planar direction such as in a direction along the substrate 110.

An overcoat layer OC may be disposed on the color filter layer 190 and the light blocking layer BM to planarize upper ends of the color filters 191, 193 and 195 and the various light blocking patterns. The overcoat layer OC may be a colorless light-transmitting layer that does not have a color in a visible light band. For example, the overcoat layer OC may include a colorless light-transmitting organic material such as acrylic resin.

FIG. 7 is a cross-sectional view of the first emission area EA1 of FIG. 6, illustrating the first light emitting element ED1 disposed in the first emission area EA1 and a portion of the bank structure 160 which is around the first light emitting element ED1 in the plan view. FIG. 8 is an enlarged view of area ‘A’ of FIG. 7.

Referring to FIG. 7, a material layer providing the inorganic pixel defining layer 151 may be entirely disposed on the second passivation layer 139, but may be patterned to partially expose the upper surface of the first pixel electrode AE1 to outside the inorganic pixel defining layer 151, while partially overlapping the first pixel electrode AE1. For example, the inorganic pixel defining layer 151 may expose the first pixel electrode AE1 to outside inorganic pixel defining layer 151 at a location overlapping the opening OP1 of the bank structure 160, and the first light emitting layer EL1 may be directly disposed on the first pixel electrode AE1 within the opening OP1.

The inorganic pixel defining layer 151 may include an inorganic insulating material. For example, the inorganic pixel defining layer 151 may include aluminum oxide, titanium oxide, tantalum oxide, hafnium oxide, zinc oxide, silicon oxide, silicon nitride, or silicon oxynitride.

According to an embodiment, the inorganic pixel defining layer 151 may be disposed on the first pixel electrode AE1 but may be spaced apart from the upper surface of the first pixel electrode AE1 at an end portion of the inorganic pixel defining layer 151. The inorganic pixel defining layer 151 may partially overlap the first pixel electrode AE1 at an edge thereof, but may not directly contact the first pixel electrode AE1 along the upper surface thereof, and a portion of the first light emitting layer EL1 of the first light emitting element ED1 may be extended along the upper surface of the first pixel electrode AE1 at a location between the inorganic pixel defining layer 151 and the first pixel electrode AE1 spaced apart from each other. As being in contact, elements may form an interface therebetween.

Although the relationship between the inorganic pixel defining layer 151, the first pixel electrode AE1 and the first light emitting layer EL1 has been described for ease of description, the second pixel electrode AE2 and the second light emitting layer EL2 as well as the third pixel electrode AE3 and the third light emitting layer EL3 may also include the same structure as the first pixel electrode AE1 and the first light emitting layer EL1.

Referring to FIG. 6, the bank structure 160 may include a plurality of openings OP1 through OP3 that form or define the emission areas EA1 through EA3. In other words, the openings OP1 through OP3 may be defined by the bank structure 160. The light emitting elements ED1 through ED3 of the display device 10 may be disposed to overlap the openings OP1 through OP3 of the bank structure 160.

Referring to FIG. 7, the bank structure 160 may include the first bank layer 161, the second bank layer 163, a third bank layer 165 and a fourth bank layer 167 including different metal materials and structures to play different roles. The first bank layer 161 may be the lowest layer of the bank structure 160 which is closest to the light emitting element layer 150, the fourth bank layer 167 may be the highest layer of the bank structure 160 which is furthest from the light emitting element layer 150, and the second bank layer 163 and the third bank layer 165 may be intermediate layers of the bank structure 160 which are in order along the thickness direction in a direction away from the light emitting element layer 150. Herein, the third bank layer 165 and the fourth bank layer 167 may be collectively referred to as a third bank layer.

The first bank layer 161 may be located on the inorganic pixel defining layer 151.

In some embodiments, the first bank layer 161 may include a metal material having high electrical conductivity. For example, the first bank layer 161 may include aluminum (Al). In an embodiment, the first bank layer 161 and the second bank layer 163 are electrically conductive, and the third bank layer 165 is electrically insulative.

The first bank layer 161 may be electrically connected to the common electrodes CE1 through CE3 of different light emitting elements ED1 through ED3. The common electrodes CE1 through CE3 of the light emitting elements ED1 through ED3 disposed in different emission areas EA1 through EA3 may not be directly connected to each other but may be electrically connected through the first bank layer 161 of the bank structure 160. Therefore, the light emitting layers EL1 through EL3 and the common electrodes CE1 through CE3 may directly contact the side surfaces of the first bank layer 161 which define the various openings and may have lower electrical resistance as the contact area between respective common electrodes and the conductive bank layer increases.

Referring to FIGS. 7 and 8, the first bank layer 161 may include a first surface 161a at which the first bank layer 161 is in contact with the inorganic pixel defining layer 151 and side surfaces 161c which define the opening OP1. The first surface 161a of the first bank layer 161 may be extended along the inorganic pixel defining layer 151, and the side surfaces 161c of the first bank layer 161 may be extended at an angle between the first direction X and the third direction Z.

The display device 10 according to the embodiment may include the bank structure 160 that forms the emission areas EA1 through EA3. In a method of providing the display device 10, the bank structure 160 may be formed by deposition and etching processes rather than a mask process. Accordingly, the first bank layer 161 may be formed by a wet etching process.

The second bank layer 163 may be located on the first bank layer 161.

The second bank layer 163 may include a highly stable metal material. For example, the second bank layer 163 may include molybdenum (Mo). Therefore, a structure including the first bank layer 161 and the second bank layer 163 may be an aluminum (Al)/molybdenum (Mo) structure.

Since the second bank layer 163 includes a more stable material than the first bank layer 161, the second bank layer 163 located on the first bank layer 161 may suppress the formation of an Al hillock (a shape in which aluminum rises like a hill) and the creation of a void (an empty space created when aluminum is pushed from one position to another) in a subsequent process. In addition, the second bank layer 163 may be electrically connected to the common electrodes CE1 through CE3 of different light emitting elements ED1 through ED3. The common electrodes CE1 through CE3 of the light emitting elements ED1 through ED3 disposed in different emission areas EA1 through EA3 may not be directly connected to each other but may be electrically connected through the first bank layer 161 together with the second bank layer 163 of the bank structure 160. Therefore, the light emitting layers EL1 through EL3 and the common electrodes CE1 through CE3 may directly contact the side surfaces of the first bank layer 161 and the second bank layer 163, to define a contact area between the side surfaces and the various common electrodes. The contact area may be defined along a plane of the side surfaces, such as along the Y-Z plane of FIG. 7. Referring to FIG. 7, for example, a contact area defined between the common electrode and the first bank layer 161 is larger than a contact area defined between the light emitting layer and the first bank layer 161. A contact portion at which the common electrode and the light emitting layer respectively contact the first bank layer 161 overlaps the tip TIP of the third bank layer 165.

Referring to FIG. 8, the second bank layer 163 may include a first surface 163a in contact with the first bank layer 161 and side surfaces 163c facing (or defining) the opening OP1.

In some embodiments, the side surfaces 163c of the second bank layer 163 may be located in a direction perpendicular to the first direction X. In other words, while the side surfaces 161c of the first bank layer 161 are inclined in the first direction X with respect to the third direction Z, the side surfaces 163c of the second bank layer 163 may be located in a direction parallel to the third direction Z. In an embodiment, a thickness direction of the display device 10 is defined perpendicular to the substrate 110, the side surface 161c of the first bank layer 161 is oblique with respect to the thickness direction, the side surface 163c of the second bank layer 163 is parallel to the thickness direction, and the side surface 161c of the first bank layer 161 overlaps the tip TIP of the third bank layer, along the thickness direction.

As mentioned above, the bank structure 160 may be formed by deposition and etching processes rather than a mask process, and the second bank layer 163 may be formed by a wet etching process. The second bank layer 163 may have a lower etch rate than the first bank layer 161.

In some embodiments, a thickness W163 of the second bank layer 163 may be smaller than a thickness W161 of the first bank layer 161. For electrical stability of the display device 10, the thickness W161 of the first bank layer 161 that includes a metal material having relatively high electrical conductivity may be large, and the thickness W163 of the second bank layer 163 that provides stability to the first bank layer 161 may be smaller than the thickness W161 of the first bank layer 161. A thickness may be defined generally along the third direction Z, but in a normal direction to an underlying (or overlying) layer or surface thereof.

The third bank layer 165 may be disposed on the second bank layer 163.

The third bank layer 165 may include not a metal but an inorganic film layer having insulating and moisture-proof properties and may include, for example, silicon nitride (SiNx). In some embodiments, the third bank layer 165 may include moisture-proof and compressive stress properties. The third bank layer 165 may be etched by a dry etching process.

In some embodiments, in order to form the bank structure 160 in a method of providing a display device 10, after the third bank layer 165 is etched by a dry etching process, both side surfaces of the first bank layer 161 and the second bank layer 163 may be provided by a wet etching process. Accordingly, the third bank layer 165 may protrude toward the openings OP1 through OP3. Here, an opening may have a center in a direction along the bank layer defined by the bank structure 160 with respective openings therebetween.

As illustrated in FIG. 7, in the bank structure 160, sides of the first bank layer 161 and the second bank layer 163 may be recessed inward from sides of the third bank layer 165. Accordingly, the third bank layer 165 of the bank structure 160 may include tips TIP protruding toward the openings OP1 through OP3. The portion of the third bank layer 165 which protrudes further than side surfaces of the first bank layer 161 and the second bank layer 163, in a direction toward the center of a respective opening, defines the tips TIP. That is, an end of the third bank layer 165 which is defined by the tips TIP, is closest to the center of the respective opening and is closer to the center than the side surfaces of the first bank layer 161 and the second bank layer 163 which are disposed closest to the center.

Referring to FIG. 8, the third bank layer 165 may include a first surface 165a overlapping the protruding tips TIP and facing the second bank layer 163, a second surface 165b facing the first surface 165a, and a side surface 165c. The second surface 165b facing the first surface 165a, and the side surface 165c, may together define an end portion (or tip) of the third bank layer 165.

In some embodiments, end portions at both side surfaces 165c of the third bank layer 165 protruding toward a center of the openings OP1 through OP3 may be bent toward the substrate 110 since the third bank layer 165 includes compressive stress properties. In other words, the tips TIP protruding toward the openings OP1 through OP3 may be inclined toward the light emitting elements ED1 through ED3. Therefore, an undercut including a predetermined angle may be formed under each side surface 163c of the second bank layer 163 and each tip TIP of the third bank layer 165.

In some embodiments, an inclination angle θ formed by the first surface 165a of the third bank layer 165 and each side surface 163c of the second bank layer 163 may be less than about 90 degrees. In other words, the inclination angle θ respectively formed by the first surface 165a of the third bank layer 165, and each side surface 163c of the second bank layer 163 at a same opening, may be an acute angle. The inclination angle θ may be adjusted according to the degree of compressive stress properties of the inorganic film providing the third bank layer 165.

In some embodiments, a thickness W165 of the third bank layer 165 may be greater than the thickness W163 of the second bank layer 163 and may be smaller than the thickness W161 of the first bank layer 161.

Since the third bank layer 165 includes moisture-proof properties, the third bank layer 165 can prevent penetration of oxygen or moisture into the bank structure 160, especially at the tip thereof.

The fourth bank layer 167 may be located on the third bank layer 165.

In some embodiments, the fourth bank layer 167 may include a metal material that has low reflectivity and is relatively stable against a wet etching process. For example, the fourth bank layer 167 may include titanium (Ti).

Like the third bank layer 165, a material layer for providing the fourth bank layer 167 may entirely deposited on the third bank layer 165, and the material layer may be etched by a dry etching process. In an method providing the display device 10, after the third bank layer 165 and the fourth bank layer 167 are etched, both side surfaces of the first bank layer 161 and the second bank layer 163 may be etched by a wet etching process. Accordingly, like the third bank layer 165, the fourth bank layer 167 may define a portion protruded toward the center the openings OP1 through OP3. That is, the fourth bank layer 167 may include tips TIP closest to the center of the openings OP1 through OP3. The fourth bank layer 167 overlapping the underlying protruding tips TIP may be bent in the direction in which the tip TIP of the third bank layer 165 under the fourth bank layer 167 is bent toward the second bank layer 163. Therefore, the fourth bank layer 167 may be bent at the same angle as the third bank layer 165, and may have a cross-sectional shape or profile the same as the third bank layer 165.

The fourth bank layer 167 overlapping the protruding tips TIP may include a first surface 167a in contact with the third bank layer 165 and a second surface 167b facing the first surface 167a. In addition, the fourth bank layer 167 may include side surface 167c connecting the first surface 167a and the second surface 167b to each other. A tip TIP of the bank layer may be defined by side surfaces 165c and 167c, together with surfaces 165a and 167b. The side surfaces 165c and 167c may be aligned or coplanar with each other, without being limited thereto. In an embodiment, the inclined surface 167c of the fourth bank layer 167 is parallel to the inclined surface 165c of the third bank layer 165, and the inclined side surface 167c of the fourth bank layer 167 is aligned with the inclined side surface 165c of the third bank layer 165.

Although not illustrated, an inclination angle θ formed by the first inclined surface 167a of the fourth bank layer 167 and each side surface 163c of the second bank layer 163 may be an acute angle. The inclination angle θ may be adjusted according to the degree of compressive stress properties of the inorganic film of the third bank layer 165 located under the fourth bank layer 167.

In some embodiments, a thickness W167 of the fourth bank layer 167 may be smaller than the thickness W161 of the first bank layer 161 and the thickness W165 of the third bank layer 165.

Referring to FIG. 7, in the display device 10, since the bank structure 160 includes the protruding tips TIP, different layers can be separately formed in different emission areas EA1 through EA3 even through a deposition process. For example, even if the light emitting layers EL1 through EL3 and the common electrodes CE1 through CE3 of the light emitting elements ED1 through ED3 are formed by a deposition process without using a mask, light emitting layer material portions and common electrode material portions may be separated or disconnected from each other, by the tips TIP of the third bank layer 165 and the fourth bank layer 167. In other words, after a material layer for forming a specific layer among the light emitting layers EL1 through EL3 and the common electrodes CE1 through CE3 is formed on an entirety of a base surface of the display device 10, disconnected material portions of the material layer which are formed in unwanted areas, may be removed by etching. Through this process, different layers can be separately formed in different emission areas EA1 through EA3.

Therefore, in the display device 10, it is possible to form different light emitting elements ED1 through ED3 in different emission areas EA1 through EA3 through deposition and etching processes, without using a mask process, and it is therefore possible to omit unnecessary components from the display device 10 and minimize the area of the non-display area NDA.

As mentioned above, the common electrodes CE1 through CE3 may directly contact the side surfaces of the first bank layer 161 and the second bank layer 163. Therefore, although the common electrodes CE1 through CE3 are spaced apart from or disconnected from each other in a direction along the bank layer, the common electrodes CE1 through CE3 may be electrically connected to each other through conductive thickness portions at the first bank layer 161 and the second bank layer 163. Unlike the pixel electrodes AE1 through AE3, the common electrodes CE1 through CE3 may be implemented in the form of an electrode electrically common to all pixels, without being separated for each pixel.

Referring to FIGS. 7 and 8, the common electrodes CE1 through CE3 may completely cover areas the side surfaces 161c of the first bank layer 161 and the side surfaces 163c of the second bank layer 163 which are not covered by a light emitting layer. As mentioned above, electrical resistance may be reduced as the common electrodes CE1 through CE3 contact a maximum planar area of the first bank layer 161 and the second bank layer 163 at the respective side surfaces thereof.

In some embodiments, the area of contact (e.g., a first contact area) between the common electrodes CE1 through CE3 and the side surfaces of the first bank layer 161 may be larger than the area of contact (e.g., a second contact area) between the light emitting layers EL1 through EL3 and the side surfaces of the first bank layer 161. In a method of providing the display device 10, the material of each of the common electrodes CE1 through CE3 and the light emitting layers EL1 through EL3 may be deposited in a direction not perpendicular (or normal), but inclined to the upper surface of the substrate 110. Here, the planar area of the material disposed on each side surface of the first bank layer 161 may vary according to the angle of inclination. In some embodiments, the light emitting layers EL1 through EL3 may not contact the second bank layer 163 at an upper portion of the first bank layer 161.

Since the bank structure 160 includes the protruding tips TIP, the light emitting layers EL1 through EL3, the common electrodes CE1 through CE3, and the capping layers 159 form layers whose materials are broken or disconnected between different openings OP1 through OP3 of the bank structure 160.

Therefore, material patterns including the same materials as the light emitting layers EL1 through EL3, the common electrodes CE1 through CE3, and the capping layers 159 may remain on the bank structure 160. On such material patterns, the first through third inorganic layers 171-1 through 171-3 formed after the common electrodes CE1 through CE3 are formed, may be disposed on the bank structure 160 having the light emitting layers EL1 through EL3, the common electrodes CE1 through CE3, and the capping layers 159 thereon, to cover regions around the emission areas EA1 through EA3.

The capping layers 159 disposed on the common electrodes CE1 through CE3 may cover the common electrodes CE1 through CE3.

Referring to FIG. 6, the various material patterns of the display device 10 may include organic patterns ELP1 through ELP3, electrode patterns CEP1 through CEP3, capping patterns 159-1 through 159-3, and the first through third inorganic layers 171-1 through 171-3.

The organic patterns ELP1 through ELP3, the electrode patterns CEP1 through CEP3, and the capping patterns 159-1 through 159-3 may be disposed on the bank structure 160 and may surround the emission areas EA1 through EA3 and/or the openings OP1 through OP3. The stacked structure of the organic patterns ELP1 through ELP3, the electrode patterns CEP1 through CEP3, and the capping patterns 159-1 through 159-3 disposed around the emission areas EA1 through EA3 may be partially etched during the fabrication process of the display device 10, and thus the pattern shapes may change. Accordingly, portions of an upper surface of the fourth bank layer 167 of the bank structure 160 may not be covered by the organic patterns ELP1 through ELP3, the electrode patterns CEP1 through CEP3 and the capping patterns 159-1 through 159-3, and a trench TP may be formed in these portions by the above patterns. The upper surface of the bank layer may be exposed to outside the stacked structure, at positions adjacent to respective light emission areas or openings, by the trench TP.

The organic patterns ELP1 through ELP3 may be disposed on the fourth bank layer 167 to partially overlap the fourth bank layer 167. The organic patterns ELP1 through ELP3 may include a first organic pattern ELP1, a second organic pattern ELP2, and a third organic pattern ELP3 including the same materials as the light emitting layers EL1 through EL3 of the light emitting elements ED1 through ED3, respectively.

The first organic pattern ELP1 may include the same material as the first light emitting layer EL1 of the first light emitting element ED1. The second organic pattern ELP2 may include the same material as the second light emitting layer EL2 of the second light emitting element ED2, and the third organic pattern ELP3 may include the same material as the third light emitting layer EL3 of the third light emitting element ED3.

The organic patterns ELP1 through ELP3 may be formed in the same processes as the light emitting layers EL1 through EL3 including the same materials as the organic patterns ELP1 through ELP3, respectively. The organic patterns ELP1 through ELP3 may be respectively disposed adjacent to the emission areas EA1 through EA3 in which the light emitting layers EL1 through EL3 are disposed. For example, the first organic pattern ELP1 may be disposed on the fourth bank layer 167 around the first emission area EA1 or the first opening OP1 to surround the first opening OP1. The second organic pattern ELP2 may be disposed on the fourth bank layer 167 around the second emission area EA2 or the second opening OP2 to surround the second opening OP2. The third organic pattern ELP3 may be disposed on the fourth bank layer 167 around the third emission area EA3 or the third opening OP3 to surround the third opening OP3.

The organic patterns ELP1 through ELP3 may be traces or disconnected patterns formed by being separated from the light emitting layers EL1 through EL3 since the bank structure 160 includes the tips TIP. The light emitting layers EL1 through EL3 may be formed in the openings OP1 through OP3, and the organic patterns ELP1 through ELP3 may be separated or disconnected from the light emitting layers EL1 through EL3, by the tips TIP of the bank structure 160. That is, the organic patterns ELP1 through ELP3 may be in a same layer as the light emitting layers EL1 through EL3, respectively. As being in a same layer, elements may be formed in a same process and/or include a same material as each other, elements may be respective portions of a same material layer, elements may be on a same layer by forming an interface with a same underlying or overlying layer, etc., without being limited thereto.

As illustrated in FIG. 8, in a tip portion TIP of the bank structure 160, the first organic pattern ELP1 may cover the second surface 167b of the fourth bank layer 167, a side surface 167c of the fourth bank layer 167, and a side surface 165c of the third bank layer 165.

Although the first organic pattern ELP1 is illustrated for ease of description, each of the second organic pattern ELP2 and the third organic pattern ELP3 may also cover the second surface 167b of the fourth bank layer 167, a side surface 167c of the fourth bank layer 167, and a side surface 165c of the third bank layer 165. The organic patterns ELP1 through ELP3 may not contact the first bank layer 161 and the second bank layer 163.

The electrode patterns CEP1 through CEP3 may be disposed on the organic patterns ELP1 through ELP3, respectively. The electrode patterns CEP1 through CEP3 may include a first electrode pattern CEP1, a second electrode pattern CEP2, and a third electrode pattern CEP3 including the same materials as the common electrodes CE1 through CE3 of the light emitting elements ED1 through ED3, respectively. That is, the electrode patterns CEP1 through CEP3 may be in a same layer as the common electrodes CE1 through CE3, such as being respective patterns of a same material layer.

For example, the first electrode pattern CEP1, the second electrode pattern CEP2, and the third electrode pattern CEP3 may be directly disposed on the first organic pattern ELP1, the second organic pattern ELP2, and the third organic pattern ELP3, respectively. The arrangement relationship between the electrode patterns CEP1 through CEP3 and the organic patterns ELP1 through ELP3 may be the same as the arrangement relationship between the light emitting layers EL1 through EL3 of the light emitting elements ED1 through ED3 and the common electrodes CE1 through CE3. The electrode patterns CEP1 through CEP3 may be traces formed when deposited materials are separated from the common electrodes CE1 through CE3 since the bank structure 160 includes the tips TIP. In the display device 10, the common electrodes CE1 through CE3 can be separately formed in different areas by the tips TIP of the bank structure 160 even in a deposition process not using a mask.

As illustrated in FIG. 8, the first electrode pattern CEP1 may be disposed on the first organic pattern ELP1 to overlap a tip TIP of the bank structure 160 and may be positioned to cover the second surface 167b of the fourth bank layer 167, a side surface 167c of the fourth bank layer 167, and a side surface 165c of the third bank layer 165. That is, an organic material layer (EL+ELP) defines the light emitting layer of the light emitting element and an organic pattern which is on the fourth bank layer 167, surrounds the light emission opening and is disconnected from the light emitting layer, and an electrode material layer (CE+CDP) defines the common electrode of the light emitting element and an electrode pattern which is on the first organic pattern. The organic pattern and the electrode pattern cover the inclined side surface 165c of the third bank layer 165 and the inclined side surface 167c of the fourth bank layer 167.

In addition, due to process characteristics of the common electrodes CE1 through CE3 having high step coverage, the first electrode pattern CEP1 may further cover a portion of the first surface 165a of the third bank layer 165. In other words, the first electrode pattern CEP1 may include a cover surface CEPa covering a portion of the first surface 165a of the third bank layer 165. That is, the third bank layer 165 includes a lower tip surface CEPa extended from the inclined side surface 165c of the third bank layer 165 and toward the side surface 163c of the second bank layer 163. The electrode pattern extends from the inclined side surface 165c of the third bank layer 165 and along the lower tip surface CEPa.

In some embodiments, the first electrode pattern CEP1 may be spaced apart or disconnected from the first common electrode CE1. In other words, the cover surface CEPa of the first electrode pattern CEP1 may not overlap the first common electrode CE1 and may be spaced apart from the first common electrode CE1.

Although the first electrode pattern CEP1 is illustrated for ease of description, the second electrode pattern CEP2 and the third electrode pattern CEP3 may also have the same structure and characteristics as the first electrode pattern CEP1.

The capping patterns 159-1 through 159-3 may be disposed on the electrode patterns CEP1 through CEP3. The capping patterns 159-1 through 159-3 may include the same material as the capping layers 159 disposed on the common electrodes CE1 through CE3. The capping patterns 159-1 through 159-3 may be directly disposed on the first electrode pattern CEP1, the second electrode pattern CEP2, and the third electrode pattern CEP3, respectively. The arrangement relationship between the capping patterns 159-1 through 159-3 and the electrode patterns CEP1 through CEP3 may be the same as the arrangement relationship between the common electrodes CE1 through CE3 of the light emitting elements ED1 through ED3 and the capping layers 159. The capping patterns 159-1 through 159-3 may be traces formed when deposited materials are separated from the capping layers 159 since the bank structure 160 includes the tips TIP. That is, the capping patterns 159-1 through 159-3 may be in a same layer as the capping layers 159.

As illustrated in FIG. 8, the first capping pattern 159-1 may be disposed on the first electrode pattern CEP1 to overlap a tip TIP of the bank structure 160 and may be positioned to cover the second surface 167b of the fourth bank layer 167, a side surface 167c of the fourth bank layer 167, and a side surface 165c of the third bank layer 165. In some embodiments, the first capping pattern 159-1 may not cover the cover surface CEPa of the first electrode pattern CEP1. For example, the first capping pattern 159-1 may not contact the first bank layer 161 and the second bank layer 163.

Although the first capping pattern 159-1 is illustrated for ease of description, the second capping pattern 159-2 and the third capping pattern 159-3 also be positioned to cover the second surface 167b of the fourth bank layer 167, side surfaces 167c of the fourth bank layer 167, and side surfaces 165c of the third bank layer 165.

In some embodiments, the first through third inorganic layers 171-1 through 171-3 may be directly disposed on the capping layers 159 within the openings OP1 through OP3 of the bank structure 160, respectively.

Since the first through third inorganic layers 171-1 through 171-3 can be formed through chemical vapor deposition, they can be formed to a uniform thickness along a step of a deposited layer. For example, each of the first inorganic layer 171-1, the second inorganic layer 171-2, and the third inorganic layer 171-3 may form a thin layer even along an undercut formed by a tip TIP of the bank structure 160.

In the display device 10, the first through third inorganic layers 171-1 through 171-3 may be disposed on the same layer, but may be formed in different processes from each other during the fabrication process of the display device 10. For example, the light emitting layers EL1 through EL3 of the first through third light emitting elements ED1 through ED3 may not be formed simultaneously but may be formed in different processes. Similarly, the first through third inorganic layers 171-1 through 171-3 may be formed in different processes.

In an embodiment, the first inorganic layer 171-1 may be formed after the first common electrode CE1 is formed, the second inorganic layer 171-2 may be formed after the second common electrode CE2 is formed, and the third inorganic layer 171-3 may be formed after the third common electrode CE3 is formed. That is, the first inorganic layer 171-1 may be formed before the second light emitting element ED2 and the third light emitting element ED3, and the second inorganic layer 171-2 may be formed before the third light emitting element ED3.

The first through third inorganic layers 171-1 through 171-3 may be disposed on portions of the bank structure 160 which are around the emission areas EA1 through EA3 to have a shape extending around a border of the light emission areas. This shape may be formed by forming a respective material layer for providing the first through third inorganic layers 171-1 through 171-3 to completely cover the bank structure 160, and then partially patterning the material layer to provide the first through third inorganic layers 171-1 through 171-3.

Referring to FIGS. 7 and 8, the first inorganic layer 171-1 may be disposed on the first light emitting element ED1. The first inorganic layer 171-1 may be disposed along the first light emitting element ED1 and inner sidewalls of layers or patterns in the first opening OP1, to cover the layers or patterns. In addition, the first inorganic layer 171-1 may be disposed on the bank structure 160 to cover the first organic pattern ELP1, the first electrode pattern CEP1 and the first capping pattern 159-1 which are disposed around the first opening OP1.

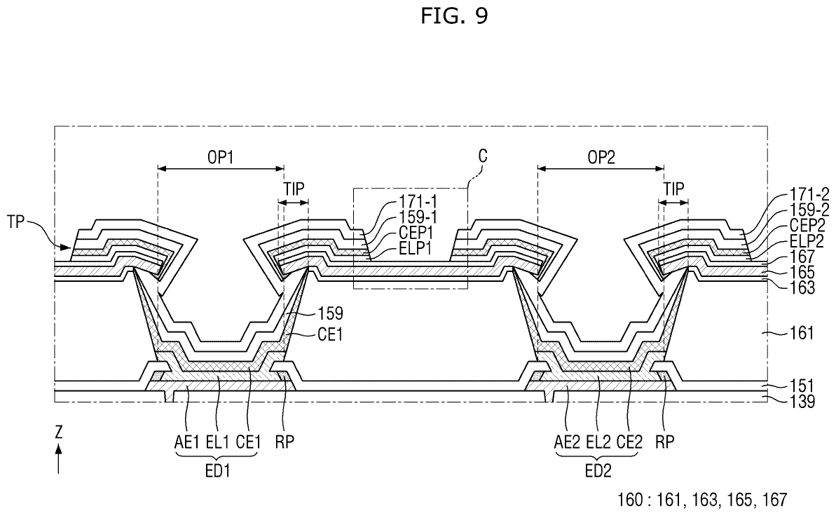

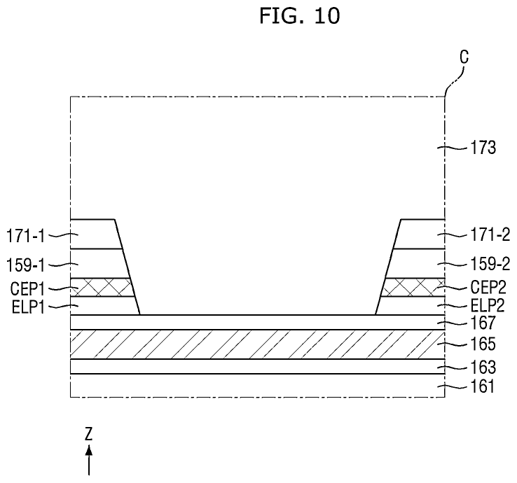

FIG. 9 is a cross-sectional view of the first emission area EA1 and the second emission area EA2 of FIG. 6. FIG. 10 is an enlarged view of area ‘C’ of FIG. 9.

Referring to FIG. 9, the second inorganic layer 171-2 may be disposed on the second light emitting element ED2 and the second capping pattern 159-2. The second inorganic layer 171-2 may be disposed along the second light emitting element ED2 and inner sidewalls of the second opening OP2 to cover them. In addition, the second inorganic layer 171-2 may be disposed on the bank structure 160 to cover the second organic pattern ELP2, the second electrode pattern CEP2 and the second capping pattern 159-2 disposed around the second opening OP2.

Referring to FIG. 10, the first inorganic layer 171-1 and the second inorganic layer 171-2 may be spaced apart from each other on the bank structure 160. Accordingly, a portion of the fourth bank layer 167 of the bank structure 160 which does not overlap the first inorganic layer 171-1 and the second inorganic layer 171-2 may be exposed to outside the stacked structure, and the exposed portion of the fourth bank layer 167 may directly contact the second encapsulation layer 173 of the thin-film encapsulation layer 170. That is, at a location between the plurality of inorganic patterns 151, the third bank layer (165+167) and the second encapsulation layer 173 contact each other.

Although the first inorganic layer 171-1 and the second inorganic layer 171-2 have been described for ease of description, the third inorganic layer 171-3 may also include the same structure and characteristics as the second inorganic layer 171-2. For example, the third inorganic layer 171-3 may also be spaced apart from the second inorganic layer 171-2.

A process in a method of fabricating the display device 10 according to the embodiment will now be described with reference to other drawings.

FIGS. 11 through 17 schematically illustrate processes in a method of forming (or providing) a bank structure 160 and light emitting elements ED1 through ED3 as a light emitting element layer 150 of the display device 10. In the following description of the process of fabricating the display device 10, the formation process of each layer will not be described, and the formation order of each layer will be described.

Referring to FIG. 11, a plurality of pixel electrodes AE1 through AE3, sacrificial layers SFL as a plurality of sacrificial patterns, an inorganic pixel defining layer 151, and a plurality of bank material layers 161L, 163L, 165L and 167L as preliminary bank materials layers, are formed on a thin-film transistor layer 130.

Although not illustrated in the drawing, the thin-film transistor layer 130 may be disposed on a substrate 110. That is, the transistor layer may be considered as including a substrate 110. The structure of each thin-film transistor TFT is the same as that described above with reference to FIG. 6, and thus a detailed description thereof will be omitted.

The pixel electrodes AE1 through AE3 may be spaced apart from each other on the thin-film transistor layer 130, in a direction along the transistor layer. The pixel electrodes AE1 through AE3 may include a first pixel electrode AE1, a second pixel electrode AE2, and a third pixel electrode AE3 of different light emitting elements ED1 through ED3. The first through third pixel electrodes AE1 through AE3 may be spaced apart from each other on the thin-film transistor layer 130.

The sacrificial layers SFL may be respectively disposed on the pixel electrodes AE1 through AE3. The sacrificial layers SFL disposed on the pixel electrodes AE1 through AE3 may be partially removed in a subsequent process to form empty spaces in which light emitting layers EL1 through EL3 are to be disposed. The sacrificial layers SFL may prevent upper surfaces of the pixel electrodes AE1 through AE3 from contacting the inorganic pixel defining layer 151. The sacrificial layers SFL may be removed to form empty spaces respectively between the pixel electrodes AE1 through AE3, and the inorganic pixel defining layer 151. In an embodiment, the sacrificial layers SFL may include an oxide semiconductor. For example, the sacrificial layers SFL may include at least one of indium gallium zinc oxide (IGZO), zinc tin oxide (ZTO), and indium tin oxide (IZO).

The inorganic pixel defining layer 151 and the bank material layers 161L, 163L, 165L and 167L may be disposed on the sacrificial layers SFL. The inorganic pixel defining layer 151 may be disposed to entirely cover the sacrificial layers SFL and the thin-film transistor layer 130 (e.g., cover an entirety thereof), and the bank material layers 161L, 163L, 165L and 167L may be disposed to entirely cover the inorganic pixel defining layer 151.

The bank material layers may include a first bank material layer 161L as a first preliminary bank layer, a second bank material layer 163L as a second preliminary bank layer, a third bank material layer 165L as a third preliminary bank layer, and a fourth bank material layer 167L as a fourth preliminary bank layer. The first bank material layer 161L may be directly disposed on the inorganic pixel defining layer 151, and the second bank material layer 163L, the third bank material layer 165L and the fourth bank material layer 167L may be sequentially disposed on the first bank material layer 161L. The bank material layers 161L, 163L, 165L and 167L may be partially etched in a subsequent process to respectively form the first through fourth bank layers 161, 163, 165 and 167 of the bank structure 160 illustrated in FIG. 6. The first bank material layer 161L may be the same as the first bank layer 161, and the second bank material layer 163L may be the same as the second bank layer 163. In addition, the third bank material layer 165L may be the same as the third bank layer 165, and the fourth bank material layer 167L may be the same as the fourth bank layer 167.

In some embodiments, the first bank material layer 161L, the second bank material layer 163L, and the fourth bank material layer 167L may include a metal material, and the third bank material layer 165L may include an inorganic material.

Since the first through fourth bank material layers 161L, 163L, 165L and 167L are substantially the same as the above-described first through fourth bank layers 161, 163, 165 and 167, respectively, a detailed description will be omitted.

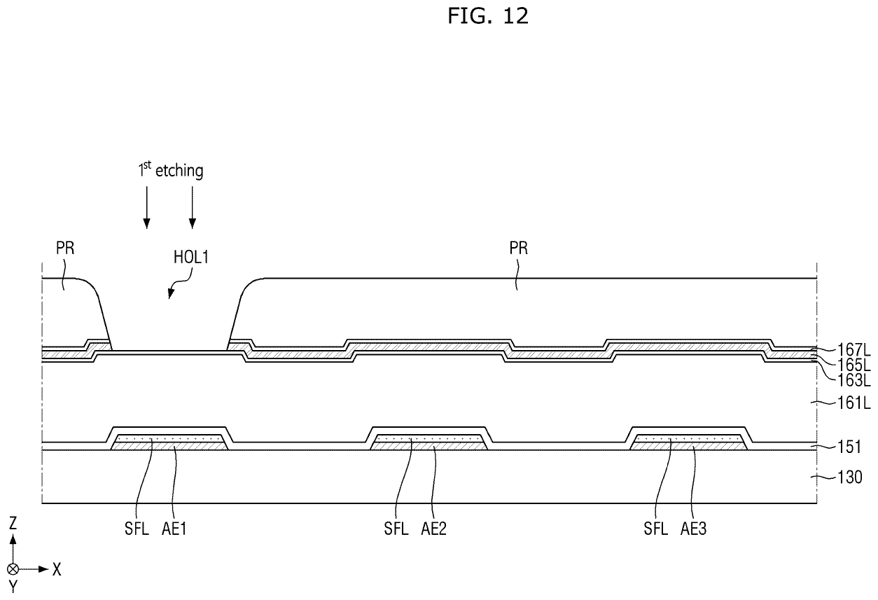

Next, referring to FIG. 12, a photoresist PR (e.g., a first photoresist) is formed on the fourth bank material layer 167L, and a first etching process for partially etching the first through fourth bank material layers 161L, 163L, 165L and 167L is performed using the photoresist PR as a mask. In this process, a first hole HOL1 may be formed.

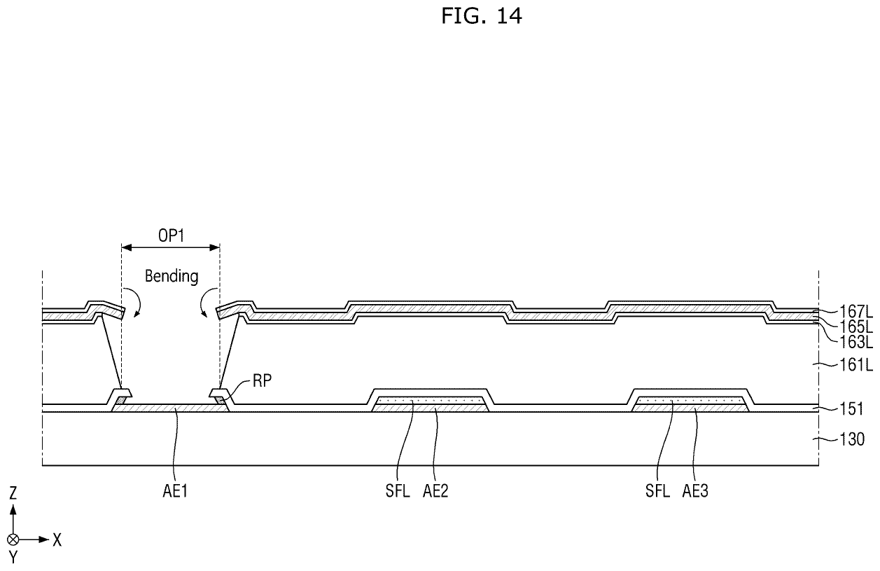

In an embodiment, the first etching process may be performed as dry etching. In the current process, the third bank material layer 165L and the fourth bank material layer 167L may be etched together to partially expose the second bank material layer 163L thereunder. The first hole HOL1 may be formed in an area overlapping the first pixel electrode AE1. The first hole HOL1 may form a part of an opening OP1 (see FIG. 14) of the bank structure 160.

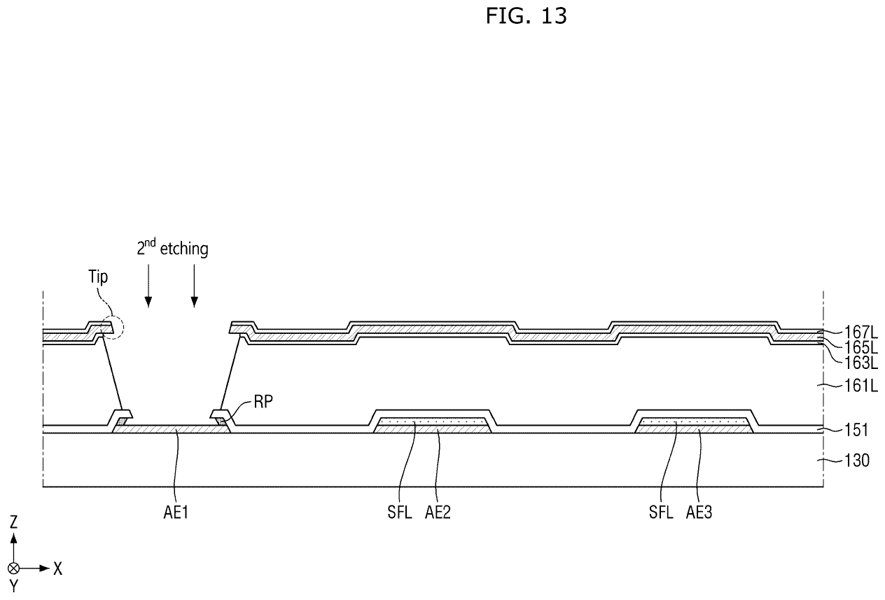

Next, referring to FIG. 13, a second etching process is performed to remove portions of the first bank material layer 161L, the second bank material layer 163L, and a sacrificial layer SFL which correspond to the first hole HOL1. In an embodiment, the sacrificial layer SFL may include an oxide semiconductor layer.

A sidewall of each of the third bank material layer 165L and the fourth bank material layer 167L are exposed at the first hole HOL1. The second etching process may be performed as a wet etching process. The second etching process may further expose sidewalls of underlying layers. In the current process, as the sacrificial layer SFL is removed, inner sidewalls of layers which are exposed at the first hole HOL1 may be isotropically etched.

The first bank material layer 161L among the first bank material layer 161L and the second bank material layer 163L may have a higher etch rate than the second bank material layer 163L. As the first bank material layer 161L and the second bank material layer 163L are etched, tips TIP protruding further than sides of the first bank material layer 161L may be formed on the third bank material layer 165L and the fourth bank material layer 167L which are not etched by wet etching.

Therefore, sides of the second bank material layer 163L may have undercuts formed under the tips TIP of the third bank material layer 165L and the fourth bank material layer 167L. Although not illustrated in the drawing, the first hole HOL1 may form a first opening OP1 or a first emission area EA1 through the second etching process.

In some embodiments, a portion of the sacrificial layer SFL which is exposed by the first hole HOL1 and a portion of the sacrificial layer SFL which is disposed between the inorganic pixel defining layer 151 and the first pixel electrode AE1 may be removed. However, the sacrificial layer SFL may not be completely removed but a portion thereof may remain as residual patterns RP between the inorganic pixel defining layer 151 and the first pixel electrode AE1. Therefore, as a portion formed by the removal of the sacrificial layer SFL, an empty space may be formed between the first pixel electrode AE1 and the inorganic pixel defining layer 151 disposed on the first pixel electrode AE1. In a subsequent process, a first light emitting layer EL1 may be formed on the first pixel electrode AE1 to fill the space.

As illustrated in FIG. 14, the tips TIP formed by the process of FIG. 13 may be bent toward the pixel electrode AE1 due to compressive stress properties of the third bank material layer 165L. The degree to which the third bank material layer 165L is bent may be modified by adjusting the compressive stress properties of the third bank material layer 165L. As the third bank material layer 165L is bent, the fourth bank material layer 167L disposed on the third bank material layer 165L may also be bent. That is, the third bank material layer 165L may be bendable together with the fourth bank material layer 167L.

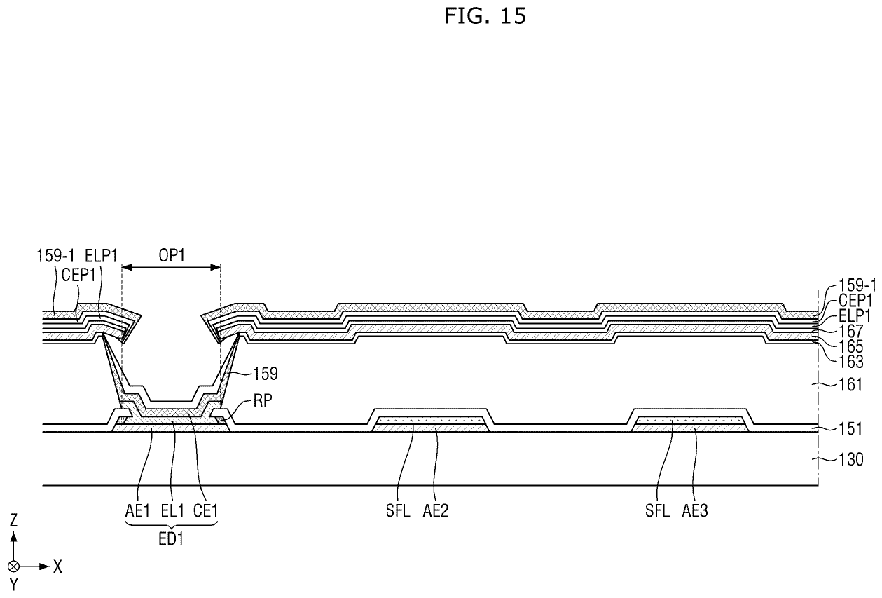

Next, referring to FIG. 15, a first light emitting element ED1 is formed by depositing the first light emitting layer EL1 and a first common electrode CE1 on the first pixel electrode AE1. In addition, a capping layer 159 is deposited to cover the first light emitting element ED1. The first light emitting layer EL1 and the first common electrode CE1 may be formed in the first opening OP1.

In the deposition process, materials that form the first light emitting layer EL1 and the first common electrode CE1 may also be deposited on the third bank material layer 165L and the fourth bank material layer 167L to form a plurality of patterns. For example, some of the materials may be deposited on the fourth bank material layer 167L to form a first organic pattern ELP1 and a first electrode pattern CEP1. In addition, the capping layer 159 may be disposed in the first opening OP1 to cover the first light emitting element ED1, and a first capping pattern 159-1 may be disposed on the fourth bank material layer 167L to cover the first organic pattern ELP1 and the first electrode pattern CEP1. The structures of the first light emitting layer EL1, the first common electrode CE1, the first organic pattern ELP1 and the first electrode pattern CEP1 are the same as those described above.

In some embodiments, the first light emitting layer EL1 and the first common electrode CE1 may be formed through a deposition process. In the first opening OP1, materials may not be smoothly deposited due to the tips TIP of the second bank material layer 163L. However, since the materials of the first light emitting layer EL1 and the first common electrode CE1 are deposited in a direction inclined to an upper surface of the substrate rather than in a direction (e.g., the third direction Z) perpendicular to the upper surface of the substrate, they may be deposited even in areas covered by or under the tips TIP of the third bank material layer 165L and the fourth bank material layer 167L.

For example, a deposition process for forming the first light emitting layer EL1 may be performed such that materials are deposited in a direction not perpendicular to the upper surface of the first pixel electrode AE1, for example, in an inclined direction between the first direction X and the third direction Z.

In an embodiment, when the angle of the deposition process for forming each of the light emitting layer EL1 through EL3 is defined as a first angle, the deposition process for forming each of the light emitting layers EL1 through EL3 may be performed at an angle of about 45 degrees to about 50 degrees relative to the upper surface of the pixel electrode AE1, AE2 or AE3. That is, the first angle may be about 45 degrees to 50 degrees.

Therefore, material of the first light emitting layer EL1 may be formed to fill the empty space between the first pixel electrode AE1 and the inorganic pixel defining layer 151, together with the residual pattern RP, and may also be formed in a part of the areas covered by the tips TIP of the first bank material layer 161L. For example, the first light emitting layer EL1 may be partially disposed in the areas covered by the tips TIP, that is, on side surfaces of the first bank material layer 161L.

A deposition process for forming the first common electrode CE1 may be performed such that materials are deposited in a direction not perpendicular to the upper surface of the first pixel electrode AE1, for example, in an inclined direction between the first direction X and the third direction Z.

In an embodiment, when the angle of the deposition process for forming each of the common electrodes CE1 through CE3 is defined as a second angle, the deposition process for forming each of the common electrodes CE1 through CE3 may be performed at an angle of about 30 degrees or less to the upper surface of the pixel electrode AE1, AE2 or AE3. That is, the second angle may be about 30 degrees or less.

In other words, the deposition process for forming the common electrodes CE1 through CE3 may be performed at an angle relatively closer to a horizontal direction than the deposition process for forming the light emitting layers EL1 through EL3. Accordingly, the common electrodes CE1 through CE3 may contact the side surfaces of the first bank layer 161 over a larger area than the light emitting layers EL1 through EL3. That is, the deposition process for forming the common electrodes CE1 through CE3 may have higher step coverage characteristics than the deposition process of forming the light emitting layers EL1 through EL3.

Therefore, the common electrodes CE1 through CE3 may be deposited to a higher position on side surfaces 161c of the first bank layer 161 than the light emitting layers EL1 through EL3 and thus may be deposited to cover side surfaces 163c of the second bank layer 163.

In some embodiments, the common electrodes CE1 through CE3 may be electrically connected to each other by contacting the first bank material layer 161L and the second bank material layer 163L having high conductivity. In the display device 10, electrical resistance may decrease as the area of contact of the common electrodes CE1 through CE3 with the first bank material layer 161L and the second bank material layer 163L increases.

In addition, unlike the first organic pattern ELP1, the first electrode pattern CEP1 may include a cover surface CEPa (see FIG. 8) that partially covers a first surface 165a of the third bank layer 165 within a range in which it does not contact the side surfaces 163c of the second bank layer 163. As mentioned above, the cover surface CEPa of the first electrode pattern CEP1 may not contact the first common electrode CE1.

In other words, the first common electrode CE1 may cover the entire side surfaces of the second bank material layer 163L but may not be connected to the first electrode pattern CEP1.

In some embodiments, if the first electrode pattern CEP1 and the first common electrode CE1 are deposited to be connected to each other, a permeation path PATH of moisture and oxygen may be formed. However, since the protruding tips TIP of the display device 10 are formed at an acute angle to the side surfaces 163c of the second bank layer 163, even if the common electrode CE is deposited at the second angle, the first electrode pattern CEP1 and the first common electrode CE1 may be deposited while being separated by the protruding tips TIP.

In other words, when the protruding tips TIP of the third bank layer 165 and the fourth bank layer 167 are inclined toward the first pixel electrode AE1, the first common electrode CE1 may not be connected to the first electrode pattern CEP1, and the permeation path PATH of moisture and oxygen through the common electrode CE may be blocked.

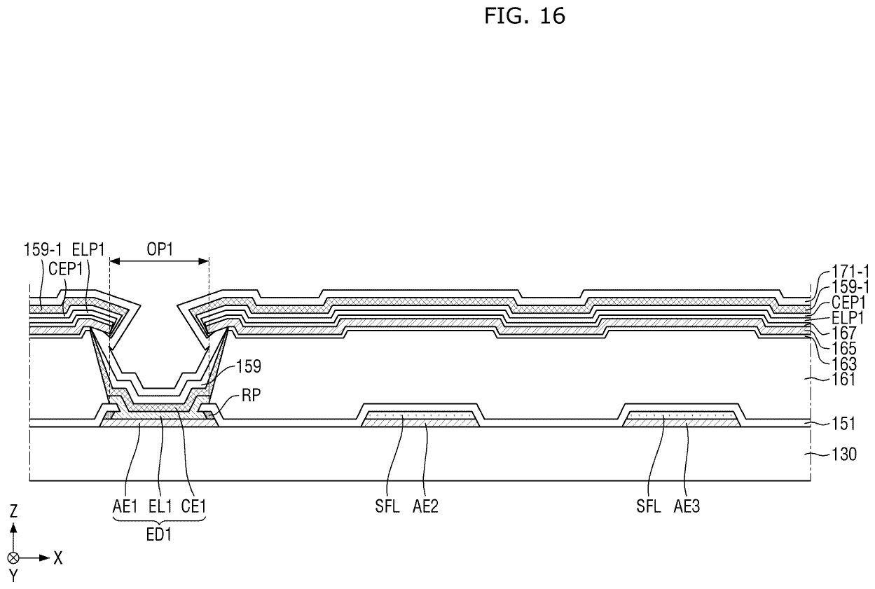

Next, referring to FIG. 16, a first inorganic layer 171-1 is formed to cover the capping layer 159 and the first capping pattern 159-1 on the first light emitting element ED1. The first inorganic layer 171-1 may be formed by a chemical vapor deposition (CVD) process and may form a uniform layer regardless of a step of a portion where it is deposited.

In some embodiments, the first inorganic layer 171-1 may be formed to completely cover an outer surface of the capping layer 159 on the first light emitting element ED1, outer surfaces of the first through fourth bank material layers 161L, 163L, 165L and 167L, and an outer surface of the first capping pattern 159-1. In particular, the first inorganic layer 171-1 may also be deposited under the tips TIP of the third bank material layer 165L and the fourth bank material layer 167L.

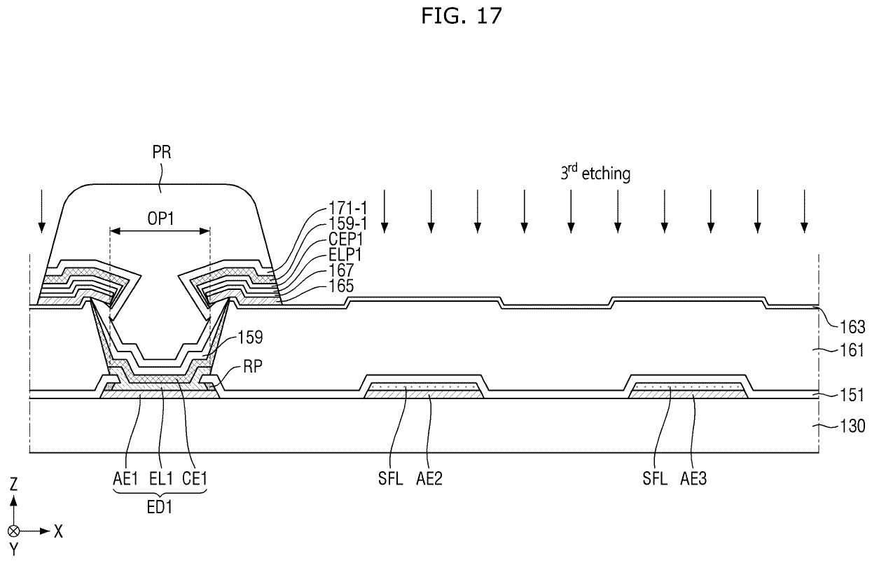

Next, referring to FIG. 17, a photoresist PR is formed on the first inorganic layer 171-1, and a third etching process is performed to partially remove the first organic pattern ELP1, the first electrode pattern CEP1, the first capping pattern 159-1, and the first inorganic layer 171-1 disposed on the first through fourth bank material layers 161L, 163L, 165L and 167L.

In the current process, the photoresist PR (e.g., a second photoresist) may be disposed to overlap the first opening OP1 or the first light emitting element ED1. The first organic pattern ELP1, the first electrode pattern CEP1, the first capping pattern 159-1, and the first inorganic layer 171-1 disposed on the first through fourth bank material layers 161L, 163L, 165L and 167L may all be removed except for a portion around the first opening OP1 or the first light emitting element ED1.

In the current process, the third bank material layer 165L and the fourth bank material layer 167L excluding a portion around the first opening OP1 or the first light emitting element ED1 may be exposed. In an embodiment, the third etching process for removing the first inorganic layer 171-1 may be performed as a dry etching process using a fluorine (F)-based etchant.

Through the above processes, the first light emitting element ED1 and the first inorganic layer 171-1 covering the first light emitting element ED1, the first organic pattern ELP1, the first electrode pattern CEP1 and the first capping pattern 159-1 may be formed.

Next, although not illustrated in the drawings, processes similar to the above-described processes may be repeated to form a second light emitting element ED2, a third light emitting element ED3, a second inorganic layer 171-2, and a third inorganic layer 171-3. Alternatively, various layers and patterns of the second light emitting element ED2, the third light emitting element ED3, the second inorganic layer 171-2, and the third inorganic layer 171-3 may be formed at the same time as corresponding layers and patterns of the first light emitting element ED1 and the first inorganic layer 171-1.

In addition, a thin-film encapsulation layer 170 (refer to FIG. 6) may be formed by forming a second encapsulation layer 173 and a third encapsulation layer 175 on a first encapsulation layer 171 and the bank structure 160. Then, a touch sensing layer 180, a light blocking layer BM, a color filter layer 190, and an overcoat layer OC may be formed to produce the display device 10.

In a display device 10 according to an embodiment, an electrode pattern located on a bank structure 160 may be separated from a common electrode, thereby blocking inflow of moisture and oxygen.

In a display device 10 according to an embodiment, it is possible to improve moisture-induced defects of the display device 10 by reducing inflow of moisture and oxygen that may occur on a bank structure 160.

In an embodiment, a display device 10 includes a pixel defining layer on the substrate 110, the pixel defining layer including a bank 160 including a first bank layer 161, a second bank layer 163 and a third bank layer (165+167), in order from the substrate 110, an inorganic pixel defining layer 151 between the first bank layer 161 and the substrate 110, and the bank 160 together with the inorganic pixel defining layer 151 defining a light emission opening, and a light emitting element which is on the substrate 110 and in the light emission opening. Each of the first bank layer 161 and the third bank layer has a side surface which defines the light emission opening, the third bank layer protrudes further than the side surface of the first bank layer 161 to define a tip TIP of the third bank layer which defines the side surface of the third bank layer, and the side surface of the third bank layer is inclined relative to the substrate 110 and defines an inclined side surface of the third bank layer.

In an embodiment, a display device 10 includes a pixel defining layer on the substrate 110, the pixel defining layer including a bank 160 including a first bank layer 161, a second bank layer 163, a third bank layer 165 and a fourth bank layer 167, in order from the substrate 110, an inorganic pixel defining layer 151 between the first bank layer 161 and the substrate 110, and the bank 160 together with the inorganic pixel defining layer 151 defining a light emission opening, and a light emitting element which is on the substrate 110 and in the light emission opening. Each of the first bank layer 161, the second bank layer 163, the third bank layer 165 and the fourth bank layer 167 layer has a side surface which defines the light emission opening. The third bank layer 165 and the fourth bank layer 167 protrude further than the side surfaces of the first bank layer 161 and the second bank layer 163, to together define a tip TIP of the bank 160 which includes the side surfaces of the third bank layer and the fourth bank layer, The side surfaces of the third bank layer and the fourth bank layer are inclined relative to the substrate 110 and define inclined side surfaces 165c and 167c of the third bank layer 165 and the fourth bank layer 167, respectively

In an embodiment, a method of providing a display device 10 includes providing a substrate including a light emitting area EA and a non-light emitting area, providing a plurality of anode electrodes (AE1, AE2 and AE3 in FIG. 11) and a sacrificial layer (SFL's in FIG. 11) each corresponding to the light emitting area, providing a pixel defining layer 151, a first bank material layer 161L, a second bank material layer 163L, a third bank material layer 165L and a fourth bank material layer 167L in order and completely covering each of the sacrificial layer, the pixel defining layer and the substrate, providing, through a dry etching process, a first hole HOL1 which overlaps an anode electrode AE1 among the plurality of anode electrodes, penetrates the third and fourth bank materials layers 165L and 167L and exposes the second bank material layer 165L to outside the third and fourth bank material layers, the third and fourth bank materials layers including sidewalls which define a portion of the first hole (at FIG. 12, for example), removing, at the first hole, portions of the second bank material layer and the sacrificial layer which correspond to the anode electrode, by wet etching, to define sidewalls of the first and second bank material layers and to expose the anode electrode to outside the first to fourth bank material layers (FIG. 12 to FIG. 13, for example), the dry etching process forming a tip TIP at which the sidewalls of the third and fourth bank materials layer protrude further than the sidewalls of the first and second bank material layer (FIGS. 12-14, for example), providing a light emitting material layer EL1+ELP1 and a cathode electrode material layer CE1+CEP1 on the fourth bank material layer and the anode electrode, to provide a light emitting layer EL1 and a cathode electrode CE1 which are in the first hole and on the anode electrode AE1 and disconnected at the tip TIP from a remaining portion of the light emitting material layer (ELP1) and a remaining portion of the cathode electrode material layer (CEP1) on the fourth bank material layer, respectively (FIG. 15), providing a first encapsulation layer 171-1 on the cathode electrode (FIG. 16) and removing respective parts of the remaining portion of the light emitting material layer, of the remaining portion of the cathode electrode material layer and of the first encapsulation layer, the respective parts being located in areas except for the light emitting area and except for an area directly around the light emitting area (FIG. 17). Referring to FIGS. 13-17, the sidewalls of the third and fourth bank material layers at the tip TIP are inclined in a direction toward the substrate 100.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a pixel defining layer on the substrate, the pixel defining layer including:
a bank comprising a first bank layer, a second bank layer and a third bank layer, in order from the substrate,
an inorganic pixel defining layer between the first bank layer and the substrate, and
the bank together with the inorganic pixel defining layer defining a light emission opening; and
a light emitting element which is on the substrate and in the light emission opening,
wherein
each of the first bank layer and the third bank layer has a side surface which defines the light emission opening,
the third bank layer protrudes further than the side surface of the first bank layer to define a tip of the third bank layer which defines the side surface of the third bank layer, and
the side surface of the third bank layer is inclined relative to the substrate and defines an inclined side surface of the third bank layer.

2. The display device of claim 1, wherein
the second bank layer further comprises a side surface which defines the light emission opening, and
the third bank layer protrudes further than the side surface of the second bank layer to define the tip of the third bank layer.

3. The display device of claim 2, wherein an angle between the side surface of the second bank layer and the inclined side surface of the third bank layer is an acute angle.

4. The display device of claim 3, wherein
a thickness of the first bank layer is greater than a thickness of the second bank layer and a thickness of the third bank layer, and
the thickness of the third bank layer is greater than the thickness of the second bank layer.

5. The display device of claim 2, wherein
a thickness direction of the display device is defined perpendicular to the substrate,
the side surface of the first bank layer is oblique with respect to the thickness direction,
the side surface of the second bank layer is parallel to the thickness direction, and
the side surface of the first bank layer overlaps the tip of the third bank layer, along the thickness direction.

6. The display device of claim 5, wherein
the light emitting element includes:
a pixel electrode which is in the light emission opening and has an upper surface furthest from the substrate,
a light emitting layer on the pixel electrode, and
a common electrode on the light emitting layer;
within the pixel defining layer, the inorganic pixel defining layer extends further than the side surface of the first bank layer to define an extended portion of the inorganic pixel defining layer, the extended portion being spaced apart from the upper surface of the pixel electrode, along the thickness direction,
the light emitting layer extends between the upper surface of the pixel electrode and the extended portion of the inorganic pixel defining layer and contacts the inorganic pixel defining layer at a contact portion, and
the contact portion overlaps the tip of the third bank layer, along the thickness direction.

7. The display device of claim 1, wherein
the light emitting element includes a pixel electrode which is in the light emission opening, a light emitting layer on the pixel electrode, and a common electrode on the light emitting layer,
the second bank layer further comprises a side surface which defines the light emission opening,
the light emitting layer contacts the side surface of the first bank layer, and
the common electrode contacts the side surface of the first bank layer and the side surface of the second bank layer.

8. The display device of claim 7, wherein
a contact area defined between the common electrode and the first bank layer is larger than a contact area defined between the light emitting layer and the first bank layer, and
a contact portion at which the common electrode and the light emitting layer respectively contact the first bank layer overlaps the tip of the third bank layer.

9. The display device of claim 8, wherein
the first bank layer and the second bank layer are electrically conductive, and
the third bank layer is electrically insulative.

10. The display device of claim 9, wherein the first bank layer comprises aluminum, the second bank layer comprises molybdenum and the third bank layer comprises silicon nitride.

11. The display device of claim 1, further comprising:
within the pixel defining layer, the bank together with the inorganic pixel defining layer define a plurality of light emission openings;
the light emitting element provided in plural including a plurality of light emitting elements spaced apart from each other along the substrate with the inorganic pixel defining layer therebetween, the plurality of light emitting elements respectively in the plurality of light emission openings;
and
an encapsulation layer on the plurality of light emitting elements and the pixel defining layer,
wherein the encapsulation layer comprises:
a first encapsulation layer, a second encapsulation layer on the first encapsulation layer and a third encapsulation layer on the second encapsulation layer,
the first encapsulation layer defining a plurality of inorganic patterns which are spaced apart from each other and respectively on the plurality of light emitting elements, and
the plurality of inorganic patterns respectively in the plurality of light emission openings and extended out of the plurality of light emission openings and along the third bank layer.

12. The display device of claim 11, wherein at a location between the plurality of inorganic patterns, the third bank layer and the second encapsulation layer contact each other.

13. The display device of claim 12, wherein at a respective emission opening among the plurality of light emission openings, an inorganic pattern among the plurality of inorganic patterns covers the inclined side surface of the third bank layer.

14. A display device comprising:
a substrate;
a pixel defining layer on the substrate, the pixel defining layer including:
a bank comprising a first bank layer, a second bank layer, a third bank layer and a fourth bank layer, in order from the substrate,
an inorganic pixel defining layer between the first bank layer and the substrate, and
the bank together with the inorganic pixel defining layer defining a light emission opening; and
a light emitting element which is on the substrate and in the light emission opening,
wherein
each of the first bank layer, the second bank layer, the third bank layer and the fourth bank layer has a side surface which defines the light emission opening,
the third bank layer and the fourth bank layer protrude further than the side surfaces of the first bank layer and the second bank layer, to together define a tip of the bank which includes the side surfaces of the third bank layer and the fourth bank layer, and
the side surfaces of the third bank layer and the fourth bank layer are inclined relative to the substrate and define inclined side surfaces of the third bank layer and the fourth bank layer, respectively.

15. The display device of claim 14, wherein the light emitting element includes a pixel electrode which is in the light emission opening, a light emitting layer on the pixel electrode, and a common electrode on the light emitting layer,
further comprising:
an organic material layer defining the light emitting layer of the light emitting element and an organic pattern which is on the fourth bank layer, surrounds the light emission opening and is disconnected from the light emitting layer; and
an electrode material layer defining the common electrode of the light emitting element and an electrode pattern which is on the first organic pattern,
wherein the organic pattern and the electrode pattern cover the inclined side surface of the third bank layer and the inclined side surface of the fourth bank layer.

16. The display device of claim 15, wherein
the third bank layer includes a lower tip surface extended from the inclined side surface of the third bank layer and toward the side surface of the second bank layer, and
the electrode pattern extends from the inclined side surface of the third bank layer and along the lower tip surface.

17. The display device of claim 16, wherein within the electrode material layer, the electrode pattern and the common electrode are disconnected from each other at the tip of the bank.

18. The display device of claim 14, wherein
the inclined surface of the fourth bank layer is parallel to the inclined surface of the third bank layer, and
the inclined side surface of the fourth bank layer is aligned with the inclined side surface of the third bank layer.

19. The display device of claim 18, wherein a thickness of the fourth bank layer is smaller than a thickness of the third bank layer.

20. A method of providing a display device, the method comprising:
providing a substrate comprising a light emitting area and a non-light emitting area;
providing a plurality of anode electrodes and a sacrificial layer each corresponding to the light emitting area;
providing a pixel defining layer, a first bank material layer, a second bank material layer, a third bank material layer and a fourth bank material layer in order and completely covering each of the sacrificial layer, the pixel defining layer and the substrate;
providing, through a dry etching process, a first hole which overlaps an anode electrode among the plurality of anode electrodes, penetrates the third and fourth bank materials layers and exposes the second bank material layer to outside the third and fourth bank material layers, the third and fourth bank materials layers including sidewalls which define a portion of the first hole;
removing, at the first hole, portions of the second bank material layer and the sacrificial layer which correspond to the anode electrode, by wet etching, to define sidewalls of the first and second bank material layers and to expose the anode electrode to outside the first to fourth bank material layers;
the dry etching process forming a tip at which the sidewalls of the third and fourth bank materials layer protrude further than the sidewalls of the first and second bank material layer;
providing a light emitting material layer and a cathode electrode material layer on the fourth bank material layer and the anode electrode, to provide a light emitting layer and a cathode electrode which are in the first hole and on the anode electrode and disconnected at the tip from a remaining portion of the light emitting material layer and a remaining portion of the cathode electrode material layer on the fourth bank material layer, respectively;
providing a first encapsulation layer on the cathode electrode; and
removing respective parts of the remaining portion of the light emitting material layer, of the remaining portion of the cathode electrode material layer and of the first encapsulation layer, the respective parts being located in areas except for the light emitting area and except for an area directly around the light emitting area,
wherein the sidewalls of the third and fourth bank material layers at the tip are inclined in a direction toward the substrate.
